(19) United States
(12) Patent Application Publication
(10) Pub. No.: US 2024/0411974 A1
(43) Pub. Date: Dec. 12, 2024

(54) PIN DENSITY-BASED CONGESTION ESTIMATION FOR ROUTABILITY-DRIVEN STANDARD CELL SYNTHESIS

(71) Applicant: NVIDIA Corp., Santa Clara, CA (US)

(72) Inventors: Chia-Tung HO, Santa Clara, CA (US); Haoxing Ren, Austin, TX (US)

(73) Assignee: NVIDIA Corp., Santa Clara, CA (US)

(21) Appl. No.: 18/330,139

(22) Filed: Jun. 6, 2023

(51) Int. Cl. G06F 30/392; G06F 30/394

(52) U.S. Cl. CPC G06F 30/392; G06F 30/394

(57) ABSTRACT

Lattice graph routability modelling mechanisms for standard cells utilizing a trained lattice graph routability model to determine routability metrics for local areas and global net connections in the standard cell. The metrics are applied to influence transistor placement in the standard cell, resulting in standard cell layouts with improved routability. Circuit layout generating processes are also described, in which a layout is formed lacking external pin assignments, and during routing of the nets for the circuit, a graph comprising virtual nodes and edges from the virtual nodes to grid locations for pins external to the circuit is generated. Routing to the external net of the circuit is performed according to the graph nodes and the graph edges.

### BACKGROUND

Standard cells are basic components of modern circuit designs. Very Large-Scale Integration (VLSI) circuits may utilize thousands or millions of standard cells in process nodes of scales smaller than 5 nm. The advance of VLSI to smaller technology nodes has resulted in a decrease in the number of available routing tracks, an increase in design rules, and stricter patterning rules for circuit fabrication. These trends result in greater constraints on the routability of standard cells.

Conventional standard cell synthesis techniques may be classified as either sequential or simultaneous. Sequential standard cell synthesis generates the transistor placement in the cell and then performs routing using mechanisms such as BonnCell and NVCell. BonnCell utilizes a tree search to explore optimal transistor placement and then formulate Mixed Integer Linear Programming (MILP) for in-cell routing. NVCell utilizes simulated annealing to generate optimal transistor placement with heuristic based routability estimations, and then employs genetic algorithms to route the placement.

These approaches focus on the local areas in the standard cell and lack the ability to estimate the routability of complex cells accurately and efficiently. For example such sequential standard cell synthesis approaches may be inefficient or incapable of generating routable cell layouts with less than five routing tracks.

Some standard cell synthesis mechanisms simultaneously perform placement and routing of transistors in the cell. Some simultaneous approaches utilize Satisfiability-Modulo-Theory (SMT) to perform simultaneous transistor placement and routing of transistors. Simultaneous smechanisms may generate more efficient routing solutions, but tend to lack the scalability of sequential approaches on large and complex standard cells.

A need therefor exists for standard cell synthesis mechanisms that generate routable, complex standard cells at advanced technology nodes.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts a system to generate a logic cell layout 102 in one embodiment.

FIG. 2 depicts a lattice graph routability model 112 configured to provide predictions for a standard cell based on the routability of local areas, interaction between local areas, and global net connections in the standard cell.

FIG. 3A and FIG. 3B depict device terminal counts for shared and not-shared diffusion regions, respectively.

FIG. 4 depicts a circuit device placement system in one embodiment.

FIG. 5A and FIG. 5B depict the determination of local area pin density in one embodiment.

FIG. 6 depicts and example of dynamic standard cell external pin allocation during routing.

FIG. 7 depicts and example algorithm to perform dynamic standard cell external pin allocation during routing.

FIG. 8A depicts external pin assignment during device placement.

FIG. 8B depicts dynamic external pin assignment during routing.

FIG. 9 depicts a circuit layout router 900 in accordance with one embodiment.

FIG. 10 depicts an incremental routing process 1000 for advanced technology nodes in one embodiment.

FIG. 11 depicts a genetic routing algorithm 1100 in accordance with one embodiment.

FIG. 12 depicts a parallel processing unit 1202 in accordance with one embodiment.

FIG. 13 depicts a general processing cluster 1300 in accordance with one embodiment.

FIG. 14 depicts a memory partition unit 1400 in accordance with one embodiment.

FIG. 15 depicts a streaming multiprocessor 1500 in accordance with one embodiment.

FIG. 16 depicts a processing system 1600 in accordance with one embodiment.

FIG. 17 depicts an exemplary processing system 1700 in accordance with another embodiment.

FIG. 18 depicts a graphics processing pipeline 1800 in accordance with one embodiment.

### DETAILED DESCRIPTION

Routability modelling mechanisms for standard cells are described. These mechanisms utilize a trained lattice graph routability model to determine routability metrics for local areas and global net connections in the standard cell. The metrics are applied to influence transistor placement in the standard cell, resulting in standard cell layouts with improved routability.

Predicting routability inside of standard cells is a challenging problem, due to its dependency on routing congestion and transistor pin accessibility, the latter being highly dependent on (i) the number of metal tracks (i.e., M0) in the cell, (ii) contact rules, (iii) the number of contact points, and (iv) the design rules for metal (i.e., M0).

Conventional mechanisms that perform placement and routing sequentially may encounter severe routability issues when the number of routing tracks is less than five, particularly in technology nodes having below 5 nm scale. Conventional mechanisms that perform simultaneous (routability-aware) placement tend to exhibit poor scalability to more complex cell layouts.

The disclosed mechanisms utilize transistor pin access, design rules, and global net routing to generate congestion and routability metrics for use in controlling device placement in standard cells. The control metrics generated by the models may be readily integrated into various conventional device placement algorithms and approaches.

Also disclosed are mechanisms to dynamic assign standard cell external pins during routing, taking into account design rule constraints.

Simulated annealing makes moves on a placement representation of the standard cell. The placement representation specifies the placement order of pins, ordering of NMOS and PMOS devices, and whether to flip a device orientation (switching the source and drain positions). Some simulated annealing mechanisms optimize an objective function, for example a weighted sum of cell width, routability estimation, and technology constraint violations. Other simulated annealing mechanisms may optimize other objectives.

The actions taken by a simulated annealing-based placer may be categorized either by the types of moves or by the targeted devices of the moves. A Flip changes the flip flag of particular devices. A Swap swaps particular devices. A Move moves particular devices to a specific location. The particular devices targeted by these operations may be either consecutive PMOS devices, consecutive NMOS devices, consecutive PMOS/NMOS device pairs, or pins. In one embodiment, the simulated annealing algorithm is implemented based on the modified Lam annealing schedule that requires no hyperparameter tuning.

For a set of PMOS and NMOS devices in a standard cell, a simulated annealing-based placer strives to place the devices along the PMOS row and the NMOS row of the cell layout while satisfying technology constraints. Pin locations for the devices may be determined during placement.

As noted above, a simulated annealing-based placer operates in steps. Each step may specify the placement order of pins, an order of NMOS and PMOS devices, and whether to flip a device orientation (switching the source and drain positions). A scoring function (e.g., a weighted sum of cell width, congestion estimation, and technology constraints may be optimized. Steps may be categorized either by types (flip, swap, move) or by the targeted devices of the step. Placements of PMOS and NMOS transistors are made along the polys of the standard cell from left to right. On some polys, a dummy device is placed, e.g., dummy PMOS placement. On some polys the transistor placements include a shared diffusion region, in other places a cut in the poly is inserted. Pin connections are made where appropriate, as well as connections to the power plane and ground plane.

In one embodiment, a routability model is provided with a logic cell netlist and layout specification (placement representation). The routability model generates metrics to influence a simulated annealing-based device placer to generate transistor placements in the cell. The transistor placements may demonstrate superior routability over placements made using conventional approaches. Once the transistor placements are made, a router is utilized with dynamic external pin allocations. The router may utilize a genetic algorithm.

This process may result in complex standard cell layouts exhibiting efficient routing in conformance with design rules for advanced technology nodes. Additionally, a multi-objective optimization may be performed to optimize the cell area, total wirelength, and routability together, for example.

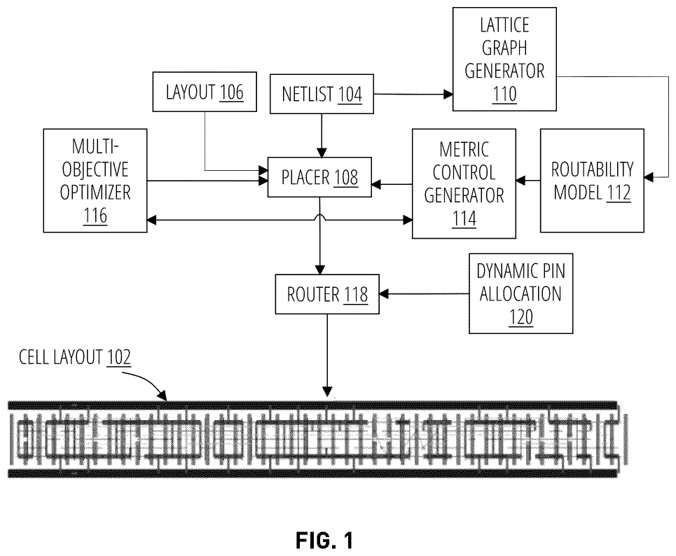

FIG. 1 depicts a system to generate a logic cell layout 102 in one embodiment. A netlist 104 and a layout template 106 for the circuit is input to a device placer 108 that places transistor devices along the layout template 106 based on device characteristics and connectivity specified in the circuit netlist 104. A lattice graph generator 110 transforms the netlist 104 into lattice graphs that are transformed by a routability model 112 into predictions (probabilities) of horizontal congestion and column-wise routability. These predictions are converted into metric controls by metric control generator 114 logic. The metric controls are applied to influence the device placements made by the placer 108. Multi-objective optimizer 116 logic is also utilized to influence the device placements. In one embodiment, a pin density metric is combined with the predicted probabilities from the routability model 112 using a weighted sum equation in the objective function for simulated annealing or other type of multi-objective optimizer. Pin density is a feature assigned to FEOL-type grid nodes in the lattice graph provided to the routability model. This graph node feature may be calculated by averaging the pin densities of the overlapped windows spanning the FEOL grid.

Because the device placements are influenced by predictions/probabilities of routability and congestion, the placer 108 is influenced to produce results for which the router 118 may more efficiently generate metal tracks. To further improve the routing of the layout, the router 118 may utilize dynamic pin allocation 120, as described more fully below.

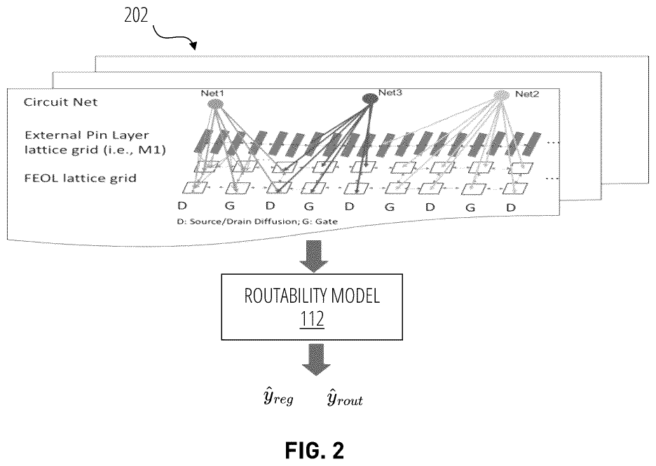

Referring to FIG. 2, a lattice graph routability model 112 is configured to provide predictions for the standard cell based on the routability of local areas, interaction between local areas, and global net connections in the standard cell.

The routability model 112 may be configured (trained) using routability probability distributions for standard cells. In one embodiment, to form a routability probability distribution for a particular standard cell, the columns of a standard cell comprising unrouted nets or terminals (i.e., unrouted column set U) may be identified, and their unroutable probability may be initialized to 1. The routability probability is spread to adjacent cell columns considering the distance and routing environment (i.e., horizontal congestion) of cell columns to construct the probability distribution, according to the following formulation:

$${P}_{rout , k} = {r}_{k} {\sum }_{{u}_{i} ∈ U} {e}^{- \frac{{( k - {u}_{i} )}^{2}}{2 {σ}^{2}}} , 0 \leq {r}_{k} \leq 1$$

In this formulation, k indicates the k^{th} column in the cell and uᵢ is the i^{th} element in unrouted column set U. Parameter σ is set based on the design rule of the pin access metal layers (e.g., the end-of-line spacing of metal layer M0, and contact rules) in half contacted poly pitch (CPP) units. Parameter rₖ is the routing environment value of the k^{th} column in the cell. The rₖ parameter may be calculated based on the horizontal routing congestion ratio as per the following formulation.

$${r}_{k} = \frac{{t}_{h , k}}{{T}_{h , k}}$$

In this formulation, t_{h,k} is the number of used horizontal routing tracks at the k^{th} column in the cell, and T_{h,k} is the number of usable horizontal routing tracks at the k^{th} column in the cell. A gaussian filter may be applied to smooth the Proms, distribution, for example:

$$\frac{1}{\sqrt{2 π} σ} {e}^{- \frac{{x}^{2}}{2 {σ}^{2}}}$$

Let [symbol] _{reg} represent the predicted horizontal congestion value of a column in the cell, and [symbol] _{reg} represent a “golden” i.e. ideal or desired horizontal congestion value for the column in the cell.

The overall loss function for backpropagation during training of the routability model 112 may be computed as:

$$L = {L}_{reg} + {L}_{rout}$$

The mean square error horizontal congestion prediction loss may be computed as:

$${L}_{reg} = - \frac{1}{{N}_{c}} \sum {( {y}_{reg} - {\hat{y}}_{reg} )}^{2}$$

Other well-known loss functions may also be utilized. In this formulation, N_{c} is the number of columns in the cell. To calculate the routability prediction loss Lᵣₒᵤₜ, calculate the log SoftMax of [symbol] ᵣₒᵤₜ and [symbol] ᵣₒᵤₜ, i.e., Yᵣₒᵤₜ, and Ŷᵣₒᵤₜ respectively, and apply KL divergence loss as follows:

$${Y}_{rout , i} = log ( \frac{{e}^{{y}_{rout , i}}}{{\sum }_{j} {e}^{{y}_{rout , j}}} ) , {\hat{Y}}_{rout , i} = log ( \frac{{e}^{{\hat{y}}_{rout , i}}}{{\sum }_{j} {e}^{{\hat{y}}_{rout , j}}} ) , i = 1 , … , {N}_{c}$$

$${L}_{rout} = {D}_{KL} ( {Y}_{rout} ‖ {\hat{Y}}_{rout} ) = {Y}_{rout} \cdot log ( \frac{{Y}_{rout}}{{\hat{Y}}_{rout}} )$$

Once the routability model 112 is trained, it may input graphs (herein, “lattice graphs”) comprising nodes and edges encoding the transistor placements, external pin placement, and circuit net connections for a standard cell. In FIG. 2, the lattice graph is depicted as organized into different layers (node types) for the circuit nets, the devices, and the external pin grid for the standard cell, with connections between the nodes in the layers. Other embodiments may utilize other structures to form the graph.

A graph neural network of the routability model 112 generates embeddings for the input lattice graph 202. The graph embeddings are applied to a shared multi-layer perceptron neural network. The output of the shared multi-layer perceptron is applied separately to (i) a multi-layer perceptron configured to predict routing congestion for the standard cell, and (ii) to a multi-layer perceptron configured to predict routability for the standard cell.

Outputs of the routability model 112 are a predicted horizontal congestion (i.e., [symbol] _{reg}) and a predicted routability (i.e., [symbol] ᵣₒᵤₜ) of each column in the transistor placement of the standard cell, as depicted in the example of FIG. 2. These predictions may be applied as controls to modify and influence the placement of transistor devices in the standard cell.

A lattice graph for a particular transistor placement comprises a front-end-of-line (FEOL) grid, an external pin grid, and a circuit net. The external pin grid may be optional for some implementations. Some standard cell placers also determine external pin location settings, and for implementations using such placers, the lattice graph 202 that are input to the routability model 112 may include the external pin placement grids to enable more accurate routability predictions.

The FEOL grid comprises feature settings for a transistor's gate, source, and drain terminals, and net information for these terminals derived from the transistor's initial placement setting (as determined by the device placer). Nodes of the FEOL grid may comprise features such as the type of transistor terminal (i.e., diffusion or gate), number of contact access points, number of required contacts, and an average pin density-aware metric at the column (this metric is described further, below).

Nodes of the FEOL grid are connected by horizontal and vertical edges. The horizontal edge between FEOL grid nodes represents a gate-to-diffusion connection. The type of connection represented by the vertical edge is dynamically determined according the circuit nets of the PMOS and NMOS regions. If the circuit nets of the PMOS and NMOS regions are the same, the vertical edge type is set to either common-gate or common-diffusion. Otherwise, the vertical edge type is set to split-gate or split-diffusion.

As noted previously, the lattice graph for a transistor placement may comprise an external pin grid. The features of the external pin grid nodes may include the usage for standard cell pins and number of via points to connect to lower metal layers. The edges of external pin grid nodes may be assigned one of two types. The first type is “external layer to external layer”, and the second type is “external layer to FEOL grid”.

The circuit net portion of a lattice graph comprises device connectivity information extracted from the standard cell netlist. A node of the circuit net comprises features such as the number of device terminals to connect at the node (#terms), vertical span, and horizontal span. The number of terminals is dynamically determined based on the diffusion sharing and diffusion break of transistor devices in the netlist.

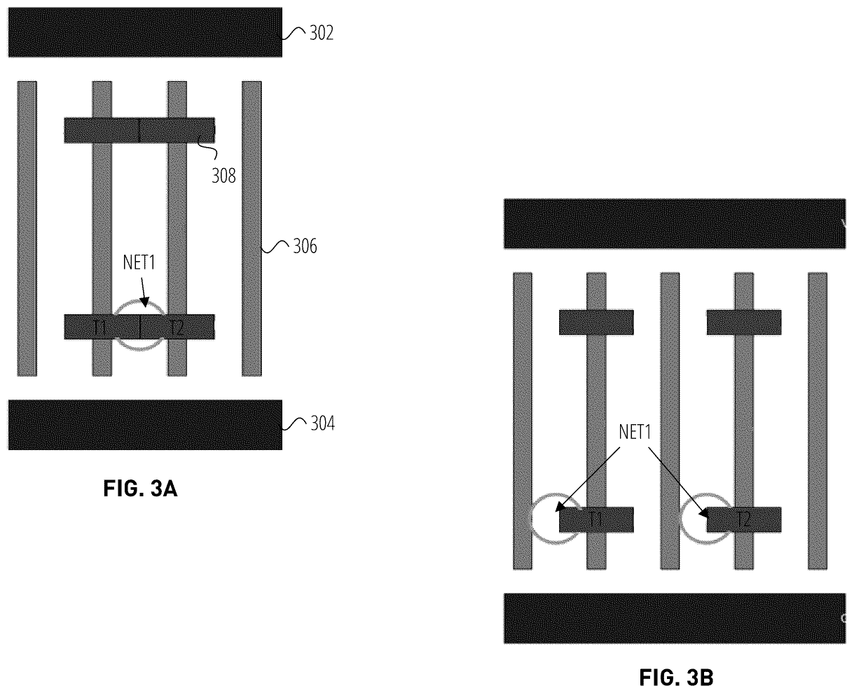

FIG. 3A depicts a circuit layout using the common stick format, showing power nets 302, ground nets 304, device gates 306, and device active regions 308. In FIG. 3A, the #terms of the Net1 node coupling transistors T1 and T2 is 0 (zero) because transistor T1 and T2 share a diffusion region. However, in FIG. 3B the #terms of the Net1 node is 2 (two) because transistor T1 and T2 are not sharing a diffusion region.

Circuit net nodes are connected by edges having two possible types. The first type is a direct terminal connection between nodes on the FEOL grid and external pins in the external pin grid. The second edge type is a span link connecting an FEOL node and an external pin node within the bounding box of the net.

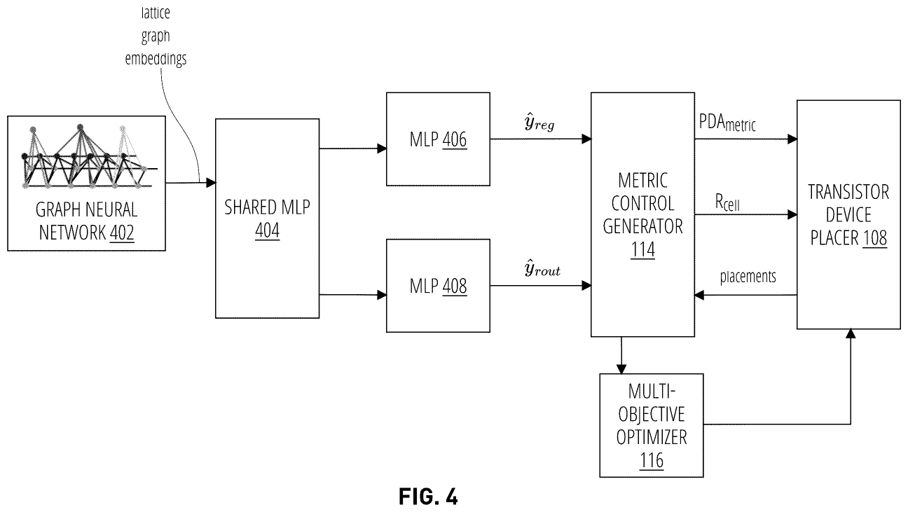

FIG. 4 depicts a circuit device placement system in one embodiment. A graph neural network 402 generates embeddings for a lattice graph. The embeddings are applied to a shared multi-layer perceptron 404, which performs processing on the embeddings that is common for both of predicting routability and predicting congestion. The common output vector of the multi-layer perceptron 404 is transformed through a routing congestion probability multi-layer perceptron 406 and a routability probability multi-layer perceptron 408 to predict [symbol] _{reg} and [symbol] ᵣₒᵤₜ, respectively.

In one embodiment, the shared multi-layer perceptron 404 comprises five fully-connected linear layers with no activations utilized in the shared multi-layer perceptron 404; the routability probability multi-layer perceptron 408 comprises five fully-connected linear layers utilizing sigmoid activation in the final output layer; and the routing congestion probability multi-layer perceptron 406 comprises three fully connected linear layers utilizing ReLU activation in the final output layer, respectively.

A metric may be formulated to jointly account for transistor pin accessibility and the global routing net together. This metric may be formulated from the predicted horizontal congestion ( [symbol] _{reg}) and the predicted routability probability (ŷᵣₒᵤₜ).

A transistor pin density map (dₚᵢₙ) of cell columns may be derived from the transistor placement. Applying element-wise multiplication of ŷ_{reg} and ŷᵣₒᵤₜ yields a product vector indicative of a level of difficulty in routing the net across each cell column. Applying element-wise multiplication of dₚᵢₙ and ŷᵣₒᵤₜ yields a product vector indicative of a level of difficulty in routing access to transistor pins in each cell column.

Cell-level routability metrics for pin access (PinAccessScore) and congestion (CongestionScope) may then be determined by applying operations such as max, sum, average, and top-k to the cell columns. A top-k metric computation that takes into account the routability that arise in local regions of the cell is:

$$PinAccessScore = TopK ( {d}_{pin} {rout}_{} ) / K$$

$$CongestionScore = TopK ( {\hat{y}}_{reg} {rout}_{} ) / K$$

A cell-level routability metric may be obtained by forming a sum of PinAccessScore and PinAccessScore to indicate a level of routing difficulty associated with a given transistor placement.

$${R}_{cell} = PinAccessScore + CongestionScore$$

The cell-level routability metric (R_{cell}) may be more efficient and accurate as a guide control for routable device placement in standard cells than conventional metrics such as max congestion, average congestion, max pin density aware congestion (PDA), and Topk PDA.

The cell-level routability metric (R_{cell}) may be integrated into the objective functions of conventional cell synthesis mechanisms. For example, the (R_{cell}) metric generated by the lattice graph routability model may be integrated into the objective functions of tree-based placement mechanisms or simulated annealing placement mechanisms as follows:

$$Minimize {w}_{a} \times Area + {w}_{l} \times TotalWireLength + {w}_{pred} \times {R}_{cell}$$

In this formulation, wₐ, wₗ, and w_{pred} are the weights of cell area, total wire length, and predicted cell-level routability metrics, respectively. In one embodiment, a multi-objective optimization process is employed to determine this minimum value. The process may utilize a multi-objective tree-structured Parzen Estimator (MOTPE) and HyperBand. MOTPE is a multi-objective Bayesian optimization algorithm for the hyperparameter optimization with categorical hyper-parameters in a tree-structure. Hyperband searches the best time allocation for each of the hyperparameter configurations. The multi-objective optimization may be carried out on the wₐ and w_{pred} parameters to optimize the cell area and routability together.

A pin density-aware congestion metric (PDA_{metric}) may be formulated from the device placements, and integrated into the objective functions of these standard cell synthesis mechanisms, for example:

$$Minimize {w}_{a} \times Area + {w}_{l} \times TotalWireLength + {w}_{pda} \times PDAMetric$$

In this objective function formulation, wₐ, wₗ, and w_{pda} are the weights of cell area, total wire length, and PDA_{metric}, respectively. The weights wₐ, wᵢ, and w_{pda} are determined by the pin density congestion in a sliding local area window of the standard cell placement. The operation to integrate these local congestion values into the weights for the objective function may be sum, maximum, average, or top-k, for example:

$${PDAMetric}_{sum} = {\sum }_{i = 1}^{N} {PDA}_{i}$$

$${PDAMetric}_{max} = {max}_{i = 1 …N} {PDA}_{i}$$

$${PDAMetric}_{avg} = \frac{{\sum }_{i = 1}^{N} {PDA}_{i}}{N}$$

In these formulations, PDAᵢ is the pin density-aware congestion in the i-th local area of the device layout.

The routability and congestion metrics may be combined into a single objective function for influencing device placements:

$$Minimize {w}_{a} \times Area + {w}_{l} \times TotalWireLength + {w}_{pda} \times PDAMetric + {w}_{pred} \times {R}_{cell}$$

In one embodiment, a multi-objective optimization may be carried out on the wₐ, w_{pred}, and w_{pda} parameters to optimize the cell area, congestion, and routability together.

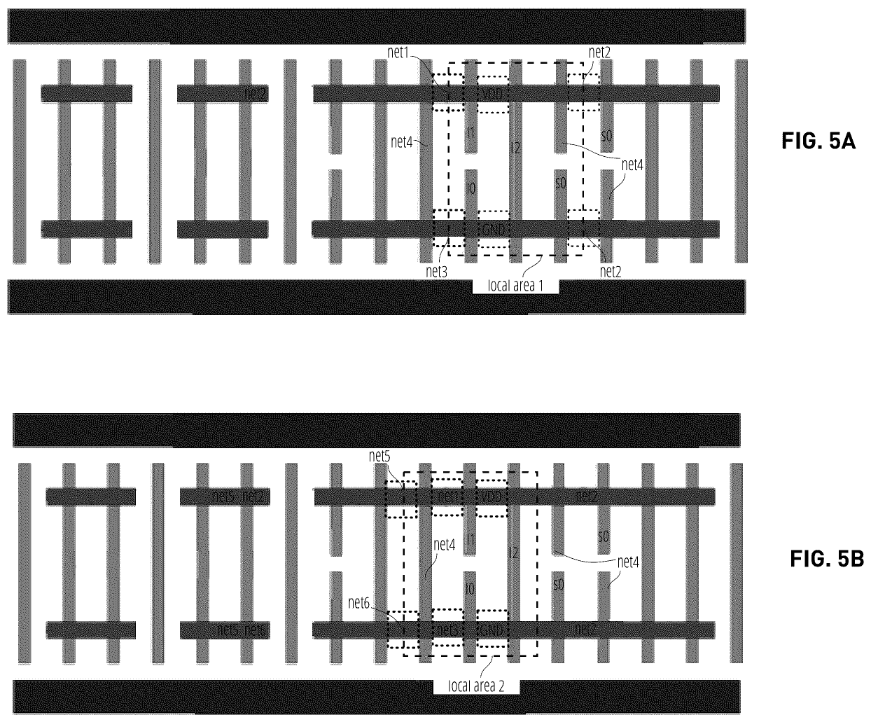

FIG. 5A and FIG. 5B depict the determination of local area pin density in one embodiment. The depicted layout is for a 4:1 multiplexer standard cell utilizing conventional CMOS technology.

A number of required contacts to a lowest metal layer (i.e., M0) is determined for a sliding window across the circuit layout. The window comprises devices and a number of crossing nets (excluding any nets that connect within the local area). The number of required contacts in a local area is determined based on the technology node definition. In the depicted example CMOS technology, for the net2 connection between the shared diffusions of the PFET and NFET devices, only one contact is needed. For power (VDD), ground (GND), and shared diffusion nets that don't extend to other transistors (e.g., net1 and net3), the number of required contacts is 0 (zero).

As a result, the number of required contacts (PDAᵢ) in the local window 1 is 6 (six). These include the contacts to access I1, I0, I2, Net4, S0, and Net2 nets. Because the crossing nets from the left side to the right side of local area 1 (e.g., net2 and net4) make connections within local area 1, the number of crossing nets is 0.

The size of the local area window utilized for the standard cell overall, or at a particular part of the layout, may be set according to the contact rules and end-of-line spacing rules for the technology node or region. For example, the window width for a cell or portion thereof may be set based on the contact rules and end-of-line spacing rules of the lowest metal layer (i.e., M0).

In the example depicted in FIG. 5B, the number of required contacts in local area 2 is 6 (six), one each for nets I1, I0, I2, net4, net5, and net6). Net2 and s0 are crossing nets that do not make contact inside local area 2, and therefor they require a connection from the left side to the right side of the local area 2. The number of crossing nets is therefor 2 (two) for local area 2, and the PDAᵢ for local area 2 is 6+2=8.

The number of required contact access and crossing nets for a local area may be weighted based on the net name or the transistor pin structure (i.e., split gate/diffusion). For example, if a particular standard cell has constraints on the numbers split gate structures in the layout, the count weight of net I1 and I0 may be made greater than 1 (one) in local area 2.

Routability problems tend to cluster in regions (hot spots) characterized by relatively large PDA congestion. The placer 108 may adjust the layout of devices to mitigate (“smooth out”) the concentration of PDA congestion in hot spot regions.

Although depicted in two dimensions, the PDA analytical process disclosed herein may be readily extended to 3D stacking standard cell technologies (i.e., Vertical FET, and Complementary FET).

One of the challenges of automated standard cell synthesis is external pin assignment. In an advanced technology nodes, external pin assignments may have a critical effect on the routability of standard cells and design rule constraints because of the limited routing resources and complex design rules (i.e., via rule, end-of-line spacing rule). Conventional mechanisms, especially sequential placement/routing mechanisms, struggle to efficiently resolve the external pin assignment challenge.

A grid-based system is common utilized for routing wires between standard cells in circuit layouts. In such a system, each metal routing layer is only used in one direction, and routes are assigned among fixed-location tracks. The track pitch is often defined as the minimum wire width plus the minimum wire space.

Grid-based routing is common for the metal layers used for inter-cell routing (typically, layers M2 or M3 and above). For a long time, grid-based routing of the nets within standard cells themselves was rarely utilized. This was because the metal routes within standard cells (e.g., metal layer M1 routes) could run off-track, change directions, change widths, and use a wide variety of via cuts.

Recently, advanced technology nodes have constrained the routing shapes within standard cells, even those on the lowest metal layers, to adhere to a fixed routing grid. This drastically reduced the set of allowable routing shapes, resulting in an environment much more amenable to automation. It also enabled well defined templates to be designed, which document all possible legal shapes that can be used in a standard cell layout.

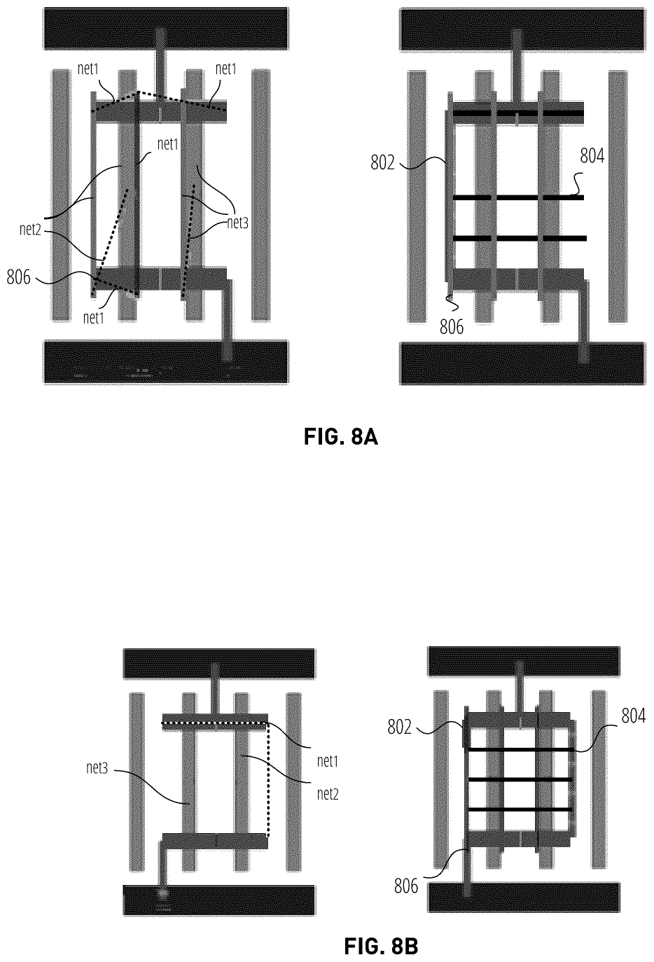

FIG. 8A and FIG. 8B depict stick diagrams for a standard cell on an advanced technology node with unidirectional metal routing. There are five layers in which nets can be routed: (i) LISD (local interconnect source-drain routing), (ii) LIG (local interconnect gate routing), M1 (routing nets inside the standard cell), and M2 and M3 (for routing between standard cells).

Layers M1 and M3 route horizontally while layer M2 routes vertically. Layer LISD connections enable limited vertical routing below the M1 layer. The LIG layer enables limited horizontal routing.

There are many restrictions on how each layer may be routed. The strictest design rule constraints are typically on the M1 layer. On the M1 layer, the routing shapes are constrained to lie on a fixed grid and cut metal shapes must be inserted between adjacent routing segments on the same track. The locations of the cut metals may be inferred from the routing assignment and have to satisfy many design rule constraints. For example, closely placed cut metal shapes need to fabricated using double patterning. This requires the number of shapes in a loop formed by the cut metals to be an even number. If the loop has an odd number of cut metals, it cannot be fabricated correctly. To define constraints for this kind of rule would require enumerating all possible loops formed by cut metals, increasing the number of constraints exponentially.

A dynamic standard cell external pin allocation mechanism may be utilized for routing the standard cell layouts generated by the device placer. The dynamic pin allocation may improve the performance and efficiency of routers such as genetic or maze routers. The dynamic standard cell external pin allocation enables the router to construct the standard cell external pin shapes dynamically based on the routability predictions and design rule constraints.

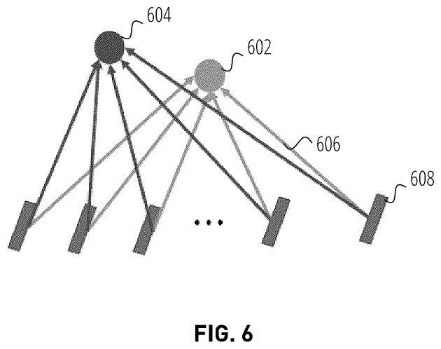

FIG. 6 depicts an example of dynamic standard cell external pin allocation during routing. A virtual node 602, 604 is created for each external net. An external net comprises connections between pins in the standard cell and other circuitry external to the standard cell. For example, the standard cell for a simple inverter has one external net for the input signal, and a second external net for the inverted output signal.

Unidirectional edges 606 are formed from the candidate external pin layer grid nodes 608 to the created virtual nodes 602, 604 of the external nets. The candidate external layer pin nodes are the pin layers and available tracks on the pin layers configured by designers of the technology nodes. The virtual nodes 602, 604 are added to the routing terminals. Virtual nodes are additional net nodes that are not defined in the external nets for the standard cell. Virtual nodes do not appear in the final standard cell layout.

The router connects the terminals of external nets through the virtual node terminals to the external pin layer grid nodes 608. As a result, the pin shape (formation of metal structures) of the external net is automatically constructed in the routing phase. This dynamic standard cell external pin allocation mechanism may be readily adopted for use with common routing mechanisms, such as Maze routing and A* search.

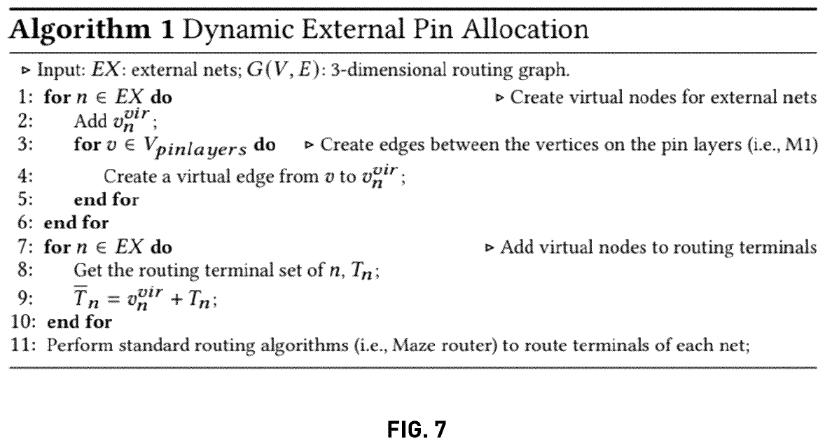

An embodiment of logic to implement this mechanism is depicted in FIG. 7. FIG. 8A depicts a standard cell layout (left) and (right) LISD layer routing 802, M2 layer routing 804, and M1 layer routing 806, using conventional mechanisms for external pin allocation during placement. In FIG. 8A, external pins are assigned during placement, at the intersection of external metal tracks (thin vertical lines) and the standard cell nets.

FIG. 8B depicts a layout for the same standard cell (left), using mechanisms in accordance with the embodiments described herein, and corresponding LISD layer routing 802, M2 layer routing 804, and M1 layer routing 806 using dynamic external pin allocation in the routing phase (right). No external pin assignments are made in the placement phase, resulting in superior routing solutions for the standard cell.

The automated standard cell layout enhancement mechanisms disclosed herein may be utilized along with reinforcement learning (RL) techniques that obviate explicit formulation of DRCs during circuit routing. Constraints are enforced by a reward given in an environment in which DRC analysis is executed independently from routing optimization. Conventional approaches seek to apply reinforcement learning to the routing problem directly, i.e., to cause a reinforcement learning agent to generate routing actions for each wire, where the action space is a routing action (North, South, West, East) for each net of a layout. Instead of making the RL agent learn the job of a maze router, the disclosed techniques learn how to fix DRCs on existing routes. The routing problem is decomposed into two independent steps: routing and DRC fixing. The DRC fixing is configured through reinforced learning and scales to large designs, because DRC problems tend to be local, while routing may utilize global information, especially for long routes.

In one embodiment, an automated layout generator in accordance with the embodiments previously described generates device placements and pin assignments. Device pairing and placement may be performed concurrently. A genetic-algorithm-based routing flow is then utilized to identify minimum routes and reduce the likelihood of DRC errors. Reinforcement learning is applied to fix DRC errors in the generated routes. Trained on one standard cell, the resulting model may be transferable to others. The model may be further retrained on each cell to improve the results.

In some embodiments, routing may be carried out in two steps: (1) a genetic algorithm-based routing step, and (2) a RL-based DRC fixing step. The genetic algorithm drives a maze router to create a routing candidate set, and the DRC RL agent reduces the number of DRCs of a given routing candidate. The DRC RL agent may for example fix M1 layer DRC errors and may in some embodiments focus solely on errors in this layer. M1 is the lowest routing layer that typically comprises the most difficult DRC issues. Other DRC errors may be corrected during maze routing. The RL ‘game’ may be configured to incrementally add additional M1 routing segments in order to reduce M1 DRCs. The observation space of the game may include the routes in M1, the DRC positions, and routing mask.

The action space may be set to be the M1 grid to be routed in a next iteration. The rewards for the game may be configured to include a small negative reward given at each step and a large positive reward associated with DRC reduction. A Proximal Policy Optimization (PPO) algorithm may be utilized in one embodiment to implement the RL agent. The policy and value networks for PPO may involve two requirements: invariance as to the number of nets, and invariance as to the cell width, i.e., WM1. Cell height HM1 may typically be constant for a given standard cell library.

The generic-algorithm-based routing algorithm may utilize routing segments as the genetic representation to facilitate the preservation of well-suited routing islands in the routing structure during genetic operations such as crossover and mutation. The fitness of each individual chromosome in a generation may be evaluated based on two metrics: (1) a number of unrouted terminal pairs, and (2) a number of DRCs. Other metrics may also be configured into the fitness function, such as a total wiring cost or Design For Manufacturing (DFM) metrics.

Therefore, in one aspect, a routing method for a circuit layout disclosed herein utilizes a genetic routing algorithm to generate the candidate routes. A reinforcement learning model is applied to correct design rule constraint errors arising from the routes. Uncorrected design rule constraints from the reinforcement learning model are applied to evolve the genetic routing algorithm, possibly along with other feedback from the RL model, such as a number of unrouted terminal pairs. The routing may be confined to an M1 layer of the circuit layout, although this is not a requirement.

The reinforcement learning model may be implemented in one embodiment with a convolutional neural network generating embeddings for at least one policy neural network and a state value neural network. The convolutional neural network may receive an image of a stick depiction of the circuit layout that the reinforcement learning model transforms into action probabilities (and a state value).

A fitness function for the genetic routing algorithm may utilize a weighted sum of a number of unrouted terminal pairs in the candidate routes and a number of the design rule constraint errors in the candidate routes. The system may also include feedback from the model of a number of the design rule constraint errors (and a number of unrouted terminal pairs) to evolve the genetic routing algorithm.

The systems may include a number of policy neural networks each including multiple fully connected layers and an operation mask. The state value neural network may also includes multiple fully connected layers. Transformation of the candidate routed circuit layouts into action probabilities and state values may be invariant in relation to a width of the stick depiction.

Artificial neural network embodiments disclosed herein include a convolutional neural network coupled to receive a circuit layout image from a genetic router, the convolutional neural network configured to transform the circuit layout image into embeddings to a plurality of policy neural networks and a state value neural network, the plurality of policy neural networks configured to transform the embeddings into action probabilities for correcting design rule constraint errors in the circuit layout image.

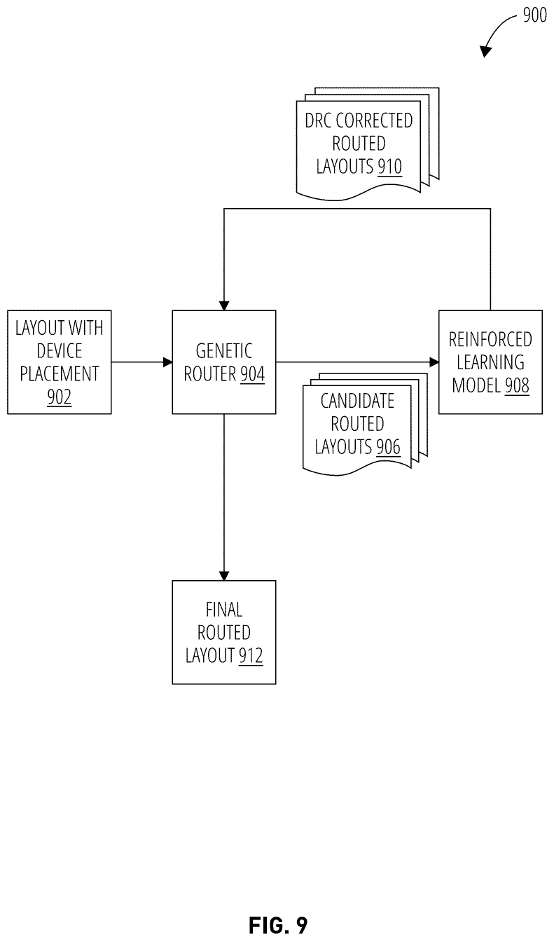

FIG. 9 depicts a circuit layout router 900 in accordance with these principles. A layout with device placement 902 is input to a genetic router 904, which generates a set of candidate routed layouts 906. The candidate routed layouts 906 are applied to a reinforced learning model 908 which corrects DRC errors detected in the candidate routed layouts 906 and returns a set of DRC corrected routed layouts 910 to the genetic router 904. The genetic router 904 evaluates the DRC corrected routed layouts 910 for fitness based, in part, on a number of uncorrected DRC errors remaining in the DRC corrected routed layouts 910. Eventually the genetic router 904 evolves one or more final routed layouts 912.

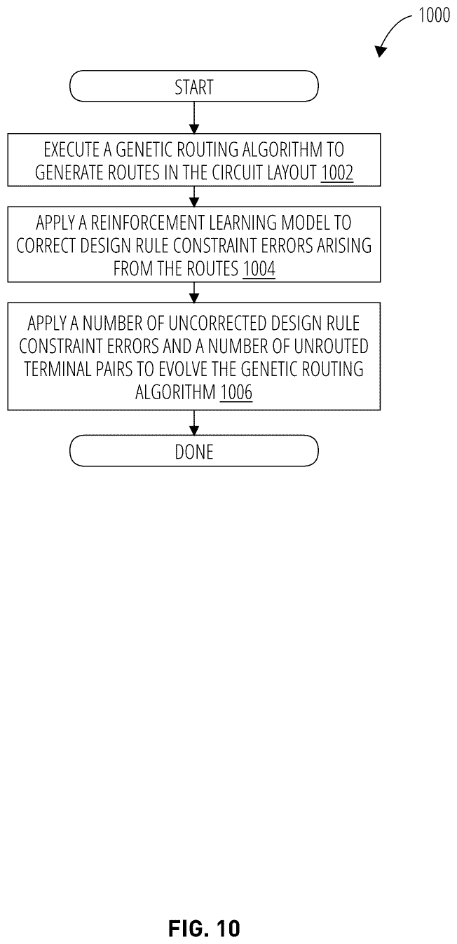

FIG. 10 depicts an incremental routing process 1000 for advanced technology nodes in one embodiment. In block 1002, the incremental routing process 1000 executes a genetic routing algorithm to generate routes in the circuit layout. In block 1004, the incremental routing process 1000 applies a reinforcement learning model to correct design rule constraint errors arising from the routes. In block 1006, the incremental routing process 1000 applies the number of uncorrected DRC errors and the number of unrouted terminal pairs in a fitness function to evolve the genetic routing algorithm.

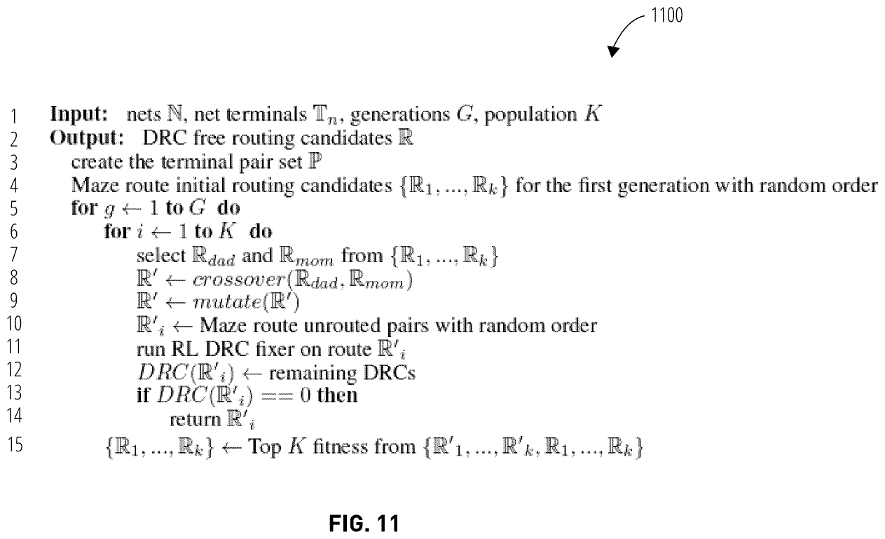

FIG. 11 depicts a genetic routing algorithm 1100 in one embodiment. Inputs to the genetic routing algorithm 1100 include a set N (1 . . . n) of circuit nets and sets of terminals Tₙ for each net n of N. Each Tₙ may be sorted left-to-right or in some other defined order (e.g., right-to-left). If sorted left-to-right, a set of terminal pairs Pₙ may be created for each net n. The union of the sets Pₙ is the global set of terminal pairs P. A “chromosome” in the genetic routing algorithm 1100 represents a possible routing solution. The set of all such chromosomes is a generation G of the genetic routing algorithm 1100. A particular chromosome Rᵢ of G is a set of terminal pairs p from the set P, and a set of (newly generated) routing segments r(p) between those terminal pairs. The routing segments r(p) may in one embodiment be generated utilizing a Lee maze router.

Each chromosome is evaluated according to a fitness function. In one embodiment the fitness function is:

$$f ( {R}_{i} ) = \frac{1}{α U ( {R}_{i} ) + β DRC ( {R}_{i} )}$$

In other words, the fitness is the reciprocal value of a weighted sum of the number of unrouted terminal pairs in Rᵢ (U(Rᵢ)) and a number of remaining DRC errors (DRC(Rᵢ)) in the chromosome (candidate routing solution) after applying reinforcement learning. In one embodiment the weight a is chosen to be larger (e.g., >2×, >3×, >5×, or one or more orders of magnitude greater) than the weight B to prioritize fully routed solutions. Other metrics (e.g., weighted terms) may be also added into this equation, such as total wiring cost or DFM metrics. Because the PPO policy is stochastic, multiple inferences of DRC RL agent on the same route and the final route with the least amount of DRCs then selected as a solution.

A pair of candidate solutions Rₘₒₘ and R_{dad} are selected from a prior generation G for crossover based on a level of fitness. In one embodiment the probability of a chromosome Rᵢ being selected for crossover is given by:

$$\frac{f ( {R}_{i} )}{{\sum }_{i} f ( {R}_{i} )}$$

In other words, candidate solutions with the highest fitness in a generation G are selected for crossover. In one embodiment crossover is carried out as follows:
Select a cut point in the chromosome. The cut can be either vertical or horizontal.
For a vertical cut, the crossover operator takes all the rₘₒₘ(p) routes that lie completely on the left hand side of the vertical cut, and all the r_{dad}(p) routes that lie completely on the right hand side of the cut, and generates a descendant in the next generation from this chromosome pair.
The crossover operator also generates another descendant in the next generation with right side routes from Rₘₒₘ and left side routes from R_{dad}.
A horizontal cut is processed similarly.

For each descendant generated by crossover, a mutation operator may randomly (with a probability of Probₘ) select a region in the candidate layout and remove any routes r(p) in the descendant that touch this region. After mutation, the remaining open terminal pairs may be routed with the maze router using a random terminal pair order.

Both initial routing and subsequent routing of unrouted terminal pairs may be carried out with a maze router that utilizes the grid space of stick representations and a Lee algorithm to search for minimum routes between two terminals. To explore more routing spaces, the maze router may execute a number I>1 iterations and select the solution with a minimum number of unrouted pairs. The maze router may also produce any random route between two terminals with the same cost (weighted routing cost per segment).

The mechanisms, algorithms, and processes described herein may be implemented by computing devices comprising instructions (stored in non-transitory media and/or memories) executed by one or more graphic processing unit (GPU) and/or general purpose data processor (e.g., a ‘central processing unit or CPU). Exemplary architectures will now be described that may be configured to carry out the techniques disclosed herein on such devices.

The following description may use certain acronyms and abbreviations as follows:
“DPC” refers to a “data processing cluster”;
“GPC” refers to a “general processing cluster”;
“I/O” refers to a “input/output”;
“L1 cache” refers to “level one cache”;
“L2 cache” refers to “level two cache”;
“LSU” refers to a “load/store unit”;
“MMU” refers to a “memory management unit”;
“MPC” refers to an “M-pipe controller”;
“PPU” refers to a “parallel processing unit”;
“PROP” refers to a “pre-raster operations unit”;
“ROP” refers to a “raster operations”;
“SFU” refers to a “special function unit”;
“SM” refers to a “streaming multiprocessor”;
“Viewport SCC” refers to “viewport scale, cull, and clip”;
“WDX” refers to a “work distribution crossbar”; and
“XBar” refers to a “crossbar”.

### Parallel Processing Unit

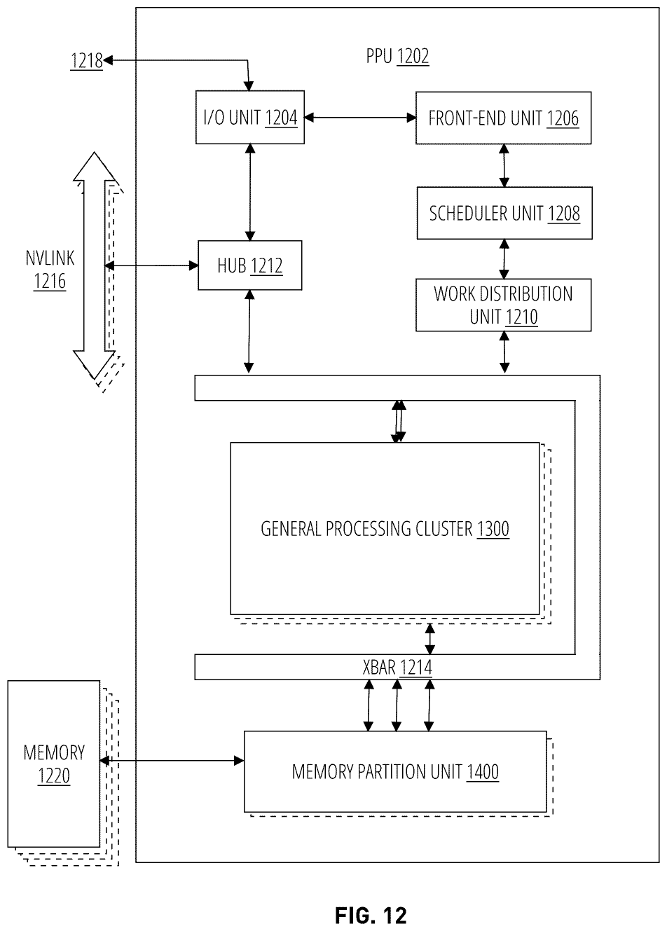

FIG. 12 depicts a parallel processing unit 1202, in accordance with an embodiment. In an embodiment, the parallel processing unit 1202 is a multi-threaded processor that is implemented on one or more integrated circuit devices. The parallel processing unit 1202 is a latency hiding architecture designed to process many threads in parallel. A thread (e.g., a thread of execution) is an instantiation of a set of instructions configured to be executed by the parallel processing unit 1202. In an embodiment, the parallel processing unit 1202 is a graphics processing unit (GPU) configured to implement a graphics rendering pipeline for processing three-dimensional (3D) graphics data in order to generate two-dimensional (2D) image data for display on a display device such as a liquid crystal display (LCD) device. In other embodiments, the parallel processing unit 1202 may be utilized for performing general-purpose computations. While one exemplary parallel processor is provided herein for illustrative purposes, it should be strongly noted that such processor is set forth for illustrative purposes only, and that any processor may be employed to supplement and/or substitute for the same.

One or more parallel processing unit 1202 modules may be configured to accelerate thousands of High Performance Computing (HPC), data center, and machine learning applications. The parallel processing unit 1202 may be configured to accelerate numerous deep learning systems and applications including autonomous vehicle platforms, deep learning, high-accuracy speech, image, and text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and the like.

As shown in FIG. 12, the parallel processing unit 1202 includes an I/O unit 1204, a front-end unit 1206, a scheduler unit 1208, a work distribution unit 1210, a hub 1212, a crossbar 1214, one or more general processing cluster 1300 modules, and one or more memory partition unit 1400 modules. The parallel processing unit 1202 may be connected to a host processor or other parallel processing unit 1202 modules via one or more high-speed NVLink 1216 interconnects. The parallel processing unit 1202 may be connected to a host processor or other peripheral devices via an interconnect 1218. The parallel processing unit 1202 may also be connected to a local memory comprising a number of memory 1220 devices. In an embodiment, the local memory may comprise a number of dynamic random access memory (DRAM) devices. The DRAM devices may be configured as a high-bandwidth memory (HBM) subsystem, with multiple DRAM dies stacked within each device. The memory 1220 may comprise logic to configure the parallel processing unit 1202 to carry out aspects of the techniques disclosed herein.

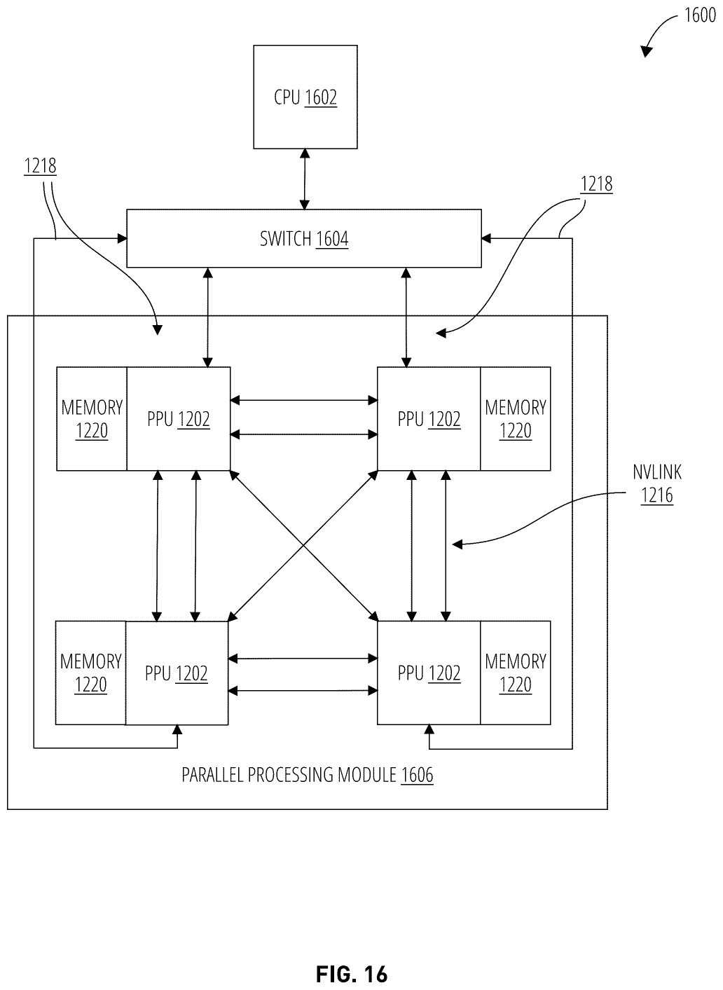

The NVLink 1216 interconnect enables systems to scale and include one or more parallel processing unit 1202 modules combined with one or more CPUs, supports cache coherence between the parallel processing unit 1202 modules and CPUs, and CPU mastering. Data and/or commands may be transmitted by the NVLink 1216 through the hub 1212 to/from other units of the parallel processing unit 1202 such as one or more copy engines, a video encoder, a video decoder, a power management unit, etc. (not explicitly shown). The NVLink 1216 is described in more detail in conjunction with FIG. 16.

The I/O unit 1204 is configured to transmit and receive communications (e.g., commands, data, etc.) from a host processor (not shown) over the interconnect 1218. The I/O unit 1204 may communicate with the host processor directly via the interconnect 1218 or through one or more intermediate devices such as a memory bridge. In an embodiment, the I/O unit 1204 may communicate with one or more other processors, such as one or more parallel processing unit 1202 modules via the interconnect 1218. In an embodiment, the I/O unit 1204 implements a Peripheral Component Interconnect Express (PCIe) interface for communications over a PCIe bus and the interconnect 1218 is a PCIe bus. In alternative embodiments, the I/O unit 1204 may implement other types of well-known interfaces for communicating with external devices.

The I/O unit 1204 decodes packets received via the interconnect 1218. In an embodiment, the packets represent commands configured to cause the parallel processing unit 1202 to perform various operations. The I/O unit 1204 transmits the decoded commands to various other units of the parallel processing unit 1202 as the commands may specify. For example, some commands may be transmitted to the front-end unit 1206. Other commands may be transmitted to the hub 1212 or other units of the parallel processing unit 1202 such as one or more copy engines, a video encoder, a video decoder, a power management unit, etc. (not explicitly shown). In other words, the I/O unit 1204 is configured to route communications between and among the various logical units of the parallel processing unit 1202.

In an embodiment, a program executed by the host processor encodes a command stream in a buffer that provides workloads to the parallel processing unit 1202 for processing. A workload may comprise several instructions and data to be processed by those instructions. The buffer is a region in a memory that is accessible (e.g., read/write) by both the host processor and the parallel processing unit 1202. For example, the I/O unit 1204 may be configured to access the buffer in a system memory connected to the interconnect 1218 via memory requests transmitted over the interconnect 1218. In an embodiment, the host processor writes the command stream to the buffer and then transmits a pointer to the start of the command stream to the parallel processing unit 1202. The front-end unit 1206 receives pointers to one or more command streams. The front-end unit 1206 manages the one or more streams, reading commands from the streams and forwarding commands to the various units of the parallel processing unit 1202.

The front-end unit 1206 is coupled to a scheduler unit 1208 that configures the various general processing cluster 1300 modules to process tasks defined by the one or more streams. The scheduler unit 1208 is configured to track state information related to the various tasks managed by the scheduler unit 1208. The state may indicate which general processing cluster 1300 a task is assigned to, whether the task is active or inactive, a priority level associated with the task, and so forth. The scheduler unit 1208 manages the execution of a plurality of tasks on the one or more general processing cluster 1300 modules.

The scheduler unit 1208 is coupled to a work distribution unit 1210 that is configured to dispatch tasks for execution on the general processing cluster 1300 modules. The work distribution unit 1210 may track a number of scheduled tasks received from the scheduler unit 1208. In an embodiment, the work distribution unit 1210 manages a pending task pool and an active task pool for each of the general processing cluster 1300 modules. The pending task pool may comprise a number of slots (e.g., 32 slots) that contain tasks assigned to be processed by a particular general processing cluster 1300. The active task pool may comprise a number of slots (e.g., 4 slots) for tasks that are actively being processed by the general processing cluster 1300 modules. As a general processing cluster 1300 finishes the execution of a task, that task is evicted from the active task pool for the general processing cluster 1300 and one of the other tasks from the pending task pool is selected and scheduled for execution on the general processing cluster 1300. If an active task has been idle on the general processing cluster 1300, such as while waiting for a data dependency to be resolved, then the active task may be evicted from the general processing cluster 1300 and returned to the pending task pool while another task in the pending task pool is selected and scheduled for execution on the general processing cluster 1300.

The work distribution unit 1210 communicates with the one or more general processing cluster 1300 modules via crossbar 1214. The crossbar 1214 is an interconnect network that couples many of the units of the parallel processing unit 1202 to other units of the parallel processing unit 1202. For example, the crossbar 1214 may be configured to couple the work distribution unit 1210 to a particular general processing cluster 1300. Although not shown explicitly, one or more other units of the parallel processing unit 1202 may also be connected to the crossbar 1214 via the hub 1212.

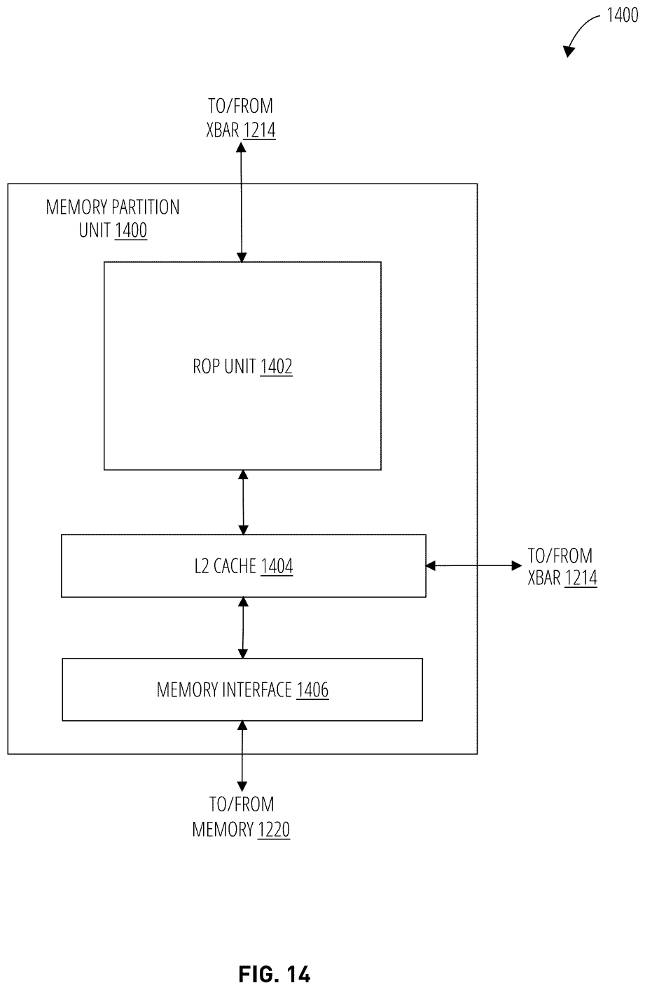

The tasks are managed by the scheduler unit 1208 and dispatched to a general processing cluster 1300 by the work distribution unit 1210. The general processing cluster 1300 is configured to process the task and generate results. The results may be consumed by other tasks within the general processing cluster 1300, routed to a different general processing cluster 1300 via the crossbar 1214, or stored in the memory 1220. The results can be written to the memory 1220 via the memory partition unit 1400 modules, which implement a memory interface for reading and writing data to/from the memory 1220. The results can be transmitted to another parallel processing unit 1202 or CPU via the NVLink 1216. In an embodiment, the parallel processing unit 1202 includes a number U of memory partition unit 1400 modules that is equal to the number of separate and distinct memory 1220 devices coupled to the parallel processing unit 1202. A memory partition unit 1400 will be described in more detail below in conjunction with FIG. 14.

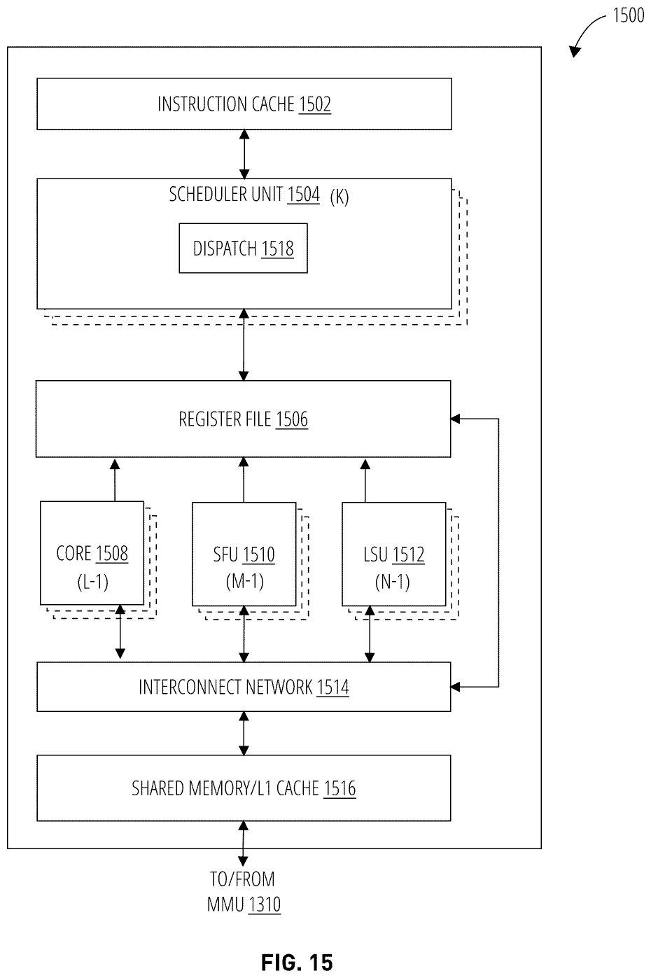

In an embodiment, a host processor executes a driver kernel that implements an application programming interface (API) that enables one or more applications executing on the host processor to schedule operations for execution on the parallel processing unit 1202. In an embodiment, multiple compute applications are simultaneously executed by the parallel processing unit 1202 and the parallel processing unit 1202 provides isolation, quality of service (QOS), and independent address spaces for the multiple compute applications. An application may generate instructions (e.g., API calls) that cause the driver kernel to generate one or more tasks for execution by the parallel processing unit 1202. The driver kernel outputs tasks to one or more streams being processed by the parallel processing unit 1202. Each task may comprise one or more groups of related threads, referred to herein as a warp. In an embodiment, a warp comprises 32 related threads that may be executed in parallel. Cooperating threads may refer to a plurality of threads including instructions to perform the task and that may exchange data through shared memory. Threads and cooperating threads are described in more detail in conjunction with FIG. 15.

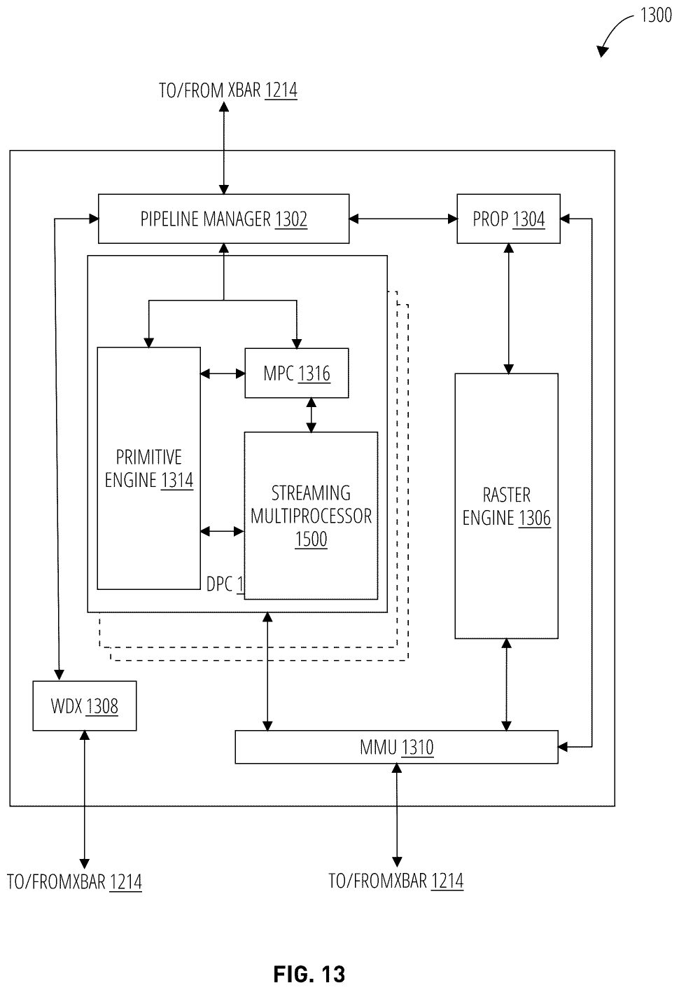

FIG. 13 depicts a general processing cluster 1300 of the parallel processing unit 1202 of FIG. 12, in accordance with an embodiment. As shown in FIG. 13, each general processing cluster 1300 includes a number of hardware units for processing tasks. In an embodiment, each general processing cluster 1300 includes a pipeline manager 1302, a pre-raster operations unit 1304, a raster engine 1306, a work distribution crossbar 1308, a memory management unit 1310, and one or more data processing cluster 1312. It will be appreciated that the general processing cluster 1300 of FIG. 13 may include other hardware units in lieu of or in addition to the units shown in FIG. 13.

In an embodiment, the operation of the general processing cluster 1300 is controlled by the pipeline manager 1302. The pipeline manager 1302 manages the configuration of the one or more data processing cluster 1312 modules for processing tasks allocated to the general processing cluster 1300. In an embodiment, the pipeline manager 1302 may configure at least one of the one or more data processing cluster 1312 modules to implement at least a portion of a graphics rendering pipeline. For example, a data processing cluster 1312 may be configured to execute a vertex shader program on the programmable streaming multiprocessor 1500. The pipeline manager 1302 may also be configured to route packets received from the work distribution unit 1210 to the appropriate logical units within the general processing cluster 1300. For example, some packets may be routed to fixed function hardware units in the pre-raster operations unit 1304 and/or raster engine 1306 while other packets may be routed to the data processing cluster 1312 modules for processing by the primitive engine 1314 or the streaming multiprocessor 1500. In an embodiment, the pipeline manager 1302 may configure at least one of the one or more data processing cluster 1312 modules to implement a neural network model and/or a computing pipeline.

The pre-raster operations unit 1304 is configured to route data generated by the raster engine 1306 and the data processing cluster 1312 modules to a Raster Operations (ROP) unit, described in more detail in conjunction with FIG. 14. The pre-raster operations unit 1304 may also be configured to perform optimizations for color blending, organize pixel data, perform address translations, and the like.

The raster engine 1306 includes a number of fixed function hardware units configured to perform various raster operations. In an embodiment, the raster engine 1306 includes a setup engine, a coarse raster engine, a culling engine, a clipping engine, a fine raster engine, and a tile coalescing engine. The setup engine receives transformed vertices and generates plane equations associated with the geometric primitive defined by the vertices. The plane equations are transmitted to the coarse raster engine to generate coverage information (e.g., an x, y coverage mask for a tile) for the primitive. The output of the coarse raster engine is transmitted to the culling engine where fragments associated with the primitive that fail a z-test are culled, and transmitted to a clipping engine where fragments lying outside a viewing frustum are clipped. Those fragments that survive clipping and culling may be passed to the fine raster engine to generate attributes for the pixel fragments based on the plane equations generated by the setup engine. The output of the raster engine 1306 comprises fragments to be processed, for example, by a fragment shader implemented within a data processing cluster 1312.

Each data processing cluster 1312 included in the general processing cluster 1300 includes an M-pipe controller 1316, a primitive engine 1314, and one or more streaming multiprocessor 1500 modules. The M-pipe controller 1316 controls the operation of the data processing cluster 1312, routing packets received from the pipeline manager 1302 to the appropriate units in the data processing cluster 1312. For example, packets associated with a vertex may be routed to the primitive engine 1314, which is configured to fetch vertex attributes associated with the vertex from the memory 1220. In contrast, packets associated with a shader program may be transmitted to the streaming multiprocessor 1500.

The streaming multiprocessor 1500 comprises a programmable streaming processor that is configured to process tasks represented by a number of threads. Each streaming multiprocessor 1500 is multi-threaded and configured to execute a plurality of threads (e.g., 32 threads) from a particular group of threads concurrently. In an embodiment, the streaming multiprocessor 1500 implements a Single-Instruction, Multiple-Data (SIMD) architecture where each thread in a group of threads (e.g., a warp) is configured to process a different set of data based on the same set of instructions. All threads in the group of threads execute the same instructions. In another embodiment, the streaming multiprocessor 1500 implements a Single-Instruction, Multiple Thread (SIMT) architecture where each thread in a group of threads is configured to process a different set of data based on the same set of instructions, but where individual threads in the group of threads are allowed to diverge during execution. In an embodiment, a program counter, call stack, and execution state is maintained for each warp, enabling concurrency between warps and serial execution within warps when threads within the warp diverge. In another embodiment, a program counter, call stack, and execution state is maintained for each individual thread, enabling equal concurrency between all threads, within and between warps. When execution state is maintained for each individual thread, threads executing the same instructions may be converged and executed in parallel for maximum efficiency. The streaming multiprocessor 1500 will be described in more detail below in conjunction with FIG. 15.

The memory management unit 1310 provides an interface between the general processing cluster 1300 and the memory partition unit 1400. The memory management unit 1310 may provide translation of virtual addresses into physical addresses, memory protection, and arbitration of memory requests. In an embodiment, the memory management unit 1310 provides one or more translation lookaside buffers (TLBs) for performing translation of virtual addresses into physical addresses in the memory 1220.

FIG. 14 depicts a memory partition unit 1400 of the parallel processing unit 1202 of FIG. 12, in accordance with an embodiment. As shown in FIG. 14, the memory partition unit 1400 includes a raster operations unit 1402, a level two cache 1404, and a memory interface 1406. The memory interface 1406 is coupled to the memory 1220. Memory interface 1406 may implement 32, 64, 128, 1024-bit data buses, or the like, for high-speed data transfer. In an embodiment, the parallel processing unit 1202 incorporates U memory interface 1406 modules, one memory interface 1406 per pair of memory partition unit 1400 modules, where each pair of memory partition unit 1400 modules is connected to a corresponding memory 1220 device. For example, parallel processing unit 1202 may be connected to up to Y memory 1220 devices, such as high bandwidth memory stacks or graphics double-data-rate, version 5, synchronous dynamic random access memory, or other types of persistent storage.

In an embodiment, the memory interface 1406 implements an HBM2 memory interface and Y equals half U. In an embodiment, the HBM2 memory stacks are located on the same physical package as the parallel processing unit 1202, providing substantial power and area savings compared with conventional GDDR5 SDRAM systems. In an embodiment, each HBM2 stack includes four memory dies and Y equals 4, with HBM2 stack including two 128-bit channels per die for a total of 8 channels and a data bus width of 1024 bits.

In an embodiment, the memory 1220 supports Single-Error Correcting Double-Error Detecting (SECDED) Error Correction Code (ECC) to protect data. ECC provides higher reliability for compute applications that are sensitive to data corruption. Reliability is especially important in large-scale cluster computing environments where parallel processing unit 1202 modules process very large datasets and/or run applications for extended periods.

In an embodiment, the parallel processing unit 1202 implements a multi-level memory hierarchy. In an embodiment, the memory partition unit 1400 supports a unified memory to provide a single unified virtual address space for CPU and parallel processing unit 1202 memory, enabling data sharing between virtual memory systems. In an embodiment the frequency of accesses by a parallel processing unit 1202 to memory located on other processors is traced to ensure that memory pages are moved to the physical memory of the parallel processing unit 1202 that is accessing the pages more frequently. In an embodiment, the NVLink 1216 supports address translation services allowing the parallel processing unit 1202 to directly access a CPU's page tables and providing full access to CPU memory by the parallel processing unit 1202.

In an embodiment, copy engines transfer data between multiple parallel processing unit 1202 modules or between parallel processing unit 1202 modules and CPUs. The copy engines can generate page faults for addresses that are not mapped into the page tables. The memory partition unit 1400 can then service the page faults, mapping the addresses into the page table, after which the copy engine can perform the transfer. In a conventional system, memory is pinned (e.g., non-pageable) for multiple copy engine operations between multiple processors, substantially reducing the available memory. With hardware page faulting, addresses can be passed to the copy engines without worrying if the memory pages are resident, and the copy process is transparent.

Data from the memory 1220 or other system memory may be fetched by the memory partition unit 1400 and stored in the level two cache 1404, which is located on-chip and is shared between the various general processing cluster 1300 modules. As shown, each memory partition unit 1400 includes a portion of the level two cache 1404 associated with a corresponding memory 1220 device. Lower level caches may then be implemented in various units within the general processing cluster 1300 modules. For example, each of the streaming multiprocessor 1500 modules may implement an L1 cache. The L1 cache is private memory that is dedicated to a particular streaming multiprocessor 1500. Data from the level two cache 1404 may be fetched and stored in each of the L1 caches for processing in the functional units of the streaming multiprocessor 1500 modules. The level two cache 1404 is coupled to the memory interface 1406 and the crossbar 1214.

The raster operations unit 1402 performs graphics raster operations related to pixel color, such as color compression, pixel blending, and the like. The raster operations unit 1402 also implements depth testing in conjunction with the raster engine 1306, receiving a depth for a sample location associated with a pixel fragment from the culling engine of the raster engine 1306. The depth is tested against a corresponding depth in a depth buffer for a sample location associated with the fragment. If the fragment passes the depth test for the sample location, then the raster operations unit 1402 updates the depth buffer and transmits a result of the depth test to the raster engine 1306. It will be appreciated that the number of partition memory partition unit 1400 modules may be different than the number of general processing cluster 1300 modules and, therefore, each raster operations unit 1402 may be coupled to each of the general processing cluster 1300 modules. The raster operations unit 1402 tracks packets received from the different general processing cluster 1300 modules and determines which general processing cluster 1300 that a result generated by the raster operations unit 1402 is routed to through the crossbar 1214. Although the raster operations unit 1402 is included within the memory partition unit 1400 in FIG. 14, in other embodiment, the raster operations unit 1402 may be outside of the memory partition unit 1400. For example, the raster operations unit 1402 may reside in the general processing cluster 1300 or another unit.

FIG. 15 illustrates the streaming multiprocessor 1500 of FIG. 13, in accordance with an embodiment. As shown in FIG. 15, the streaming multiprocessor 1500 includes an instruction cache 1502, one or more scheduler unit 1504 modules (e.g., such as scheduler unit 1208), a register file 1506, one or more processing core 1508 modules, one or more special function unit 1510 modules, one or more load/store unit 1512 modules, an interconnect network 1514, and a shared memory/L1 cache 1516.

As described above, the work distribution unit 1210 dispatches tasks for execution on the general processing cluster 1300 modules of the parallel processing unit 1202. The tasks are allocated to a particular data processing cluster 1312 within a general processing cluster 1300 and, if the task is associated with a shader program, the task may be allocated to a streaming multiprocessor 1500. The scheduler unit 1208 receives the tasks from the work distribution unit 1210 and manages instruction scheduling for one or more thread blocks assigned to the streaming multiprocessor 1500. The scheduler unit 1504 schedules thread blocks for execution as warps of parallel threads, where each thread block is allocated at least one warp. In an embodiment, each warp executes 32 threads. The scheduler unit 1504 may manage a plurality of different thread blocks, allocating the warps to the different thread blocks and then dispatching instructions from the plurality of different cooperative groups to the various functional units (e.g., core 1508 modules, special function unit 1510 modules, and load/store unit 1512 modules) during each clock cycle.

Cooperative Groups is a programming model for organizing groups of communicating threads that allows developers to express the granularity at which threads are communicating, enabling the expression of richer, more efficient parallel decompositions. Cooperative launch APIs support synchronization amongst thread blocks for the execution of parallel algorithms. Conventional programming models provide a single, simple construct for synchronizing cooperating threads: a barrier across all threads of a thread block (e.g., the syncthreads ( ) function). However, programmers would often like to define groups of threads at smaller than thread block granularities and synchronize within the defined groups to enable greater performance, design flexibility, and software reuse in the form of collective group-wide function interfaces.

Cooperative Groups enables programmers to define groups of threads explicitly at sub-block (e.g., as small as a single thread) and multi-block granularities, and to perform collective operations such as synchronization on the threads in a cooperative group. The programming model supports clean composition across software boundaries, so that libraries and utility functions can synchronize safely within their local context without having to make assumptions about convergence. Cooperative Groups primitives enable new patterns of cooperative parallelism, including producer-consumer parallelism, opportunistic parallelism, and global synchronization across an entire grid of thread blocks.

A dispatch 1518 unit is configured within the scheduler unit 1504 to transmit instructions to one or more of the functional units. In one embodiment, the scheduler unit 1504 includes two dispatch 1518 units that enable two different instructions from the same warp to be dispatched during each clock cycle. In alternative embodiments, each scheduler unit 1504 may include a single dispatch 1518 unit or additional dispatch 1518 units.

Each streaming multiprocessor 1500 includes a register file 1506 that provides a set of registers for the functional units of the streaming multiprocessor 1500. In an embodiment, the register file 1506 is divided between each of the functional units such that each functional unit is allocated a dedicated portion of the register file 1506. In another embodiment, the register file 1506 is divided between the different warps being executed by the streaming multiprocessor 1500. The register file 1506 provides temporary storage for operands connected to the data paths of the functional units.

Each streaming multiprocessor 1500 comprises L processing core 1508 modules. In an embodiment, the streaming multiprocessor 1500 includes a large number (e.g., 128, etc.) of distinct processing core 1508 modules. Each core 1508 may include a fully-pipelined, single-precision, double-precision, and/or mixed precision processing unit that includes a floating point arithmetic logic unit and an integer arithmetic logic unit. In an embodiment, the floating point arithmetic logic units implement the IEEE 754-2008 standard for floating point arithmetic. In an embodiment, the core 1508 modules include 64 single-precision (32-bit) floating point cores, 64 integer cores, 32 double-precision (64-bit) floating point cores, and 8 tensor cores.

Tensor cores configured to perform matrix operations, and, in an embodiment, one or more tensor cores are included in the core 1508 modules. In particular, the tensor cores are configured to perform deep learning matrix arithmetic, such as convolution operations for neural network training and inferencing. In an embodiment, each tensor core operates on a 4×4 matrix and performs a matrix multiply and accumulate operation D=A′B+C, where A, B, C, and D are 4×4 matrices.

In an embodiment, the matrix multiply inputs A and B are 16-bit floating point matrices, while the accumulation matrices C and D may be 16-bit floating point or 32-bit floating point matrices. Tensor Cores operate on 16-bit floating point input data with 32-bit floating point accumulation. The 16-bit floating point multiply requires 64 operations and results in a full precision product that is then accumulated using 32-bit floating point addition with the other intermediate products for a 4×4×4 matrix multiply. In practice, Tensor Cores are used to perform much larger two-dimensional or higher dimensional matrix operations, built up from these smaller elements. An API, such as CUDA 9 C++ API, exposes specialized matrix load, matrix multiply and accumulate, and matrix store operations to efficiently use Tensor Cores from a CUDA-C++ program. At the CUDA level, the warp-level interface assumes 16×16 size matrices spanning all 32 threads of the warp.

Each streaming multiprocessor 1500 also comprises M special function unit 1510 modules that perform special functions (e.g., attribute evaluation, reciprocal square root, and the like). In an embodiment, the special function unit 1510 modules may include a tree traversal unit configured to traverse a hierarchical tree data structure. In an embodiment, the special function unit 1510 modules may include texture unit configured to perform texture map filtering operations. In an embodiment, the texture units are configured to load texture maps (e.g., a 2D array of texels) from the memory 1220 and sample the texture maps to produce sampled texture values for use in shader programs executed by the streaming multiprocessor 1500. In an embodiment, the texture maps are stored in the shared memory/L1 cache 1516. The texture units implement texture operations such as filtering operations using mip-maps (e.g., texture maps of varying levels of detail). In an embodiment, each streaming multiprocessor 1500 includes two texture units.

Each streaming multiprocessor 1500 also comprises N load/store unit 1512 modules that implement load and store operations between the shared memory/L1 cache 1516 and the register file 1506. Each streaming multiprocessor 1500 includes an interconnect network 1514 that connects each of the functional units to the register file 1506 and the load/store unit 1512 to the register file 1506 and shared memory/L1 cache 1516. In an embodiment, the interconnect network 1514 is a crossbar that can be configured to connect any of the functional units to any of the registers in the register file 1506 and connect the load/store unit 1512 modules to the register file 1506 and memory locations in shared memory/L1 cache 1516.

The shared memory/L1 cache 1516 is an array of on-chip memory that allows for data storage and communication between the streaming multiprocessor 1500 and the primitive engine 1314 and between threads in the streaming multiprocessor 1500. In an embodiment, the shared memory/L1 cache 1516 comprises 128 KB of storage capacity and is in the path from the streaming multiprocessor 1500 to the memory partition unit 1400. The shared memory/L1 cache 1516 can be used to cache reads and writes. One or more of the shared memory/L1 cache 1516, level two cache 1404, and memory 1220 are backing stores.

Combining data cache and shared memory functionality into a single memory block provides the best overall performance for both types of memory accesses. The capacity is usable as a cache by programs that do not use shared memory. For example, if shared memory is configured to use half of the capacity, texture and load/store operations can use the remaining capacity. Integration within the shared memory/L1 cache 1516 enables the shared memory/L1 cache 1516 to function as a high-throughput conduit for streaming data while simultaneously providing high-bandwidth and low-latency access to frequently reused data.

When configured for general purpose parallel computation, a simpler configuration can be used compared with graphics processing. Specifically, the fixed function graphics processing units shown in FIG. 12, are bypassed, creating a much simpler programming model. In the general purpose parallel computation configuration, the work distribution unit 1210 assigns and distributes blocks of threads directly to the data processing cluster 1312 modules. The threads in a block execute the same program, using a unique thread ID in the calculation to ensure each thread generates unique results, using the streaming multiprocessor 1500 to execute the program and perform calculations, shared memory/L1 cache 1516 to communicate between threads, and the load/store unit 1512 to read and write global memory through the shared memory/L1 cache 1516 and the memory partition unit 1400. When configured for general purpose parallel computation, the streaming multiprocessor 1500 can also write commands that the scheduler unit 1208 can use to launch new work on the data processing cluster 1312 modules.

The parallel processing unit 1202 may be included in a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, and the like. In an embodiment, the parallel processing unit 1202 is embodied on a single semiconductor substrate. In another embodiment, the parallel processing unit 1202 is included in a system-on-a-chip (SoC) along with one or more other devices such as additional parallel processing unit 1202 modules, the memory 1220, a reduced instruction set computer (RISC) CPU, a memory management unit (MMU), a digital-to-analog converter (DAC), and the like.

In an embodiment, the parallel processing unit 1202 may be included on a graphics card that includes one or more memory devices. The graphics card may be configured to interface with a PCIe slot on a motherboard of a desktop computer. In yet another embodiment, the parallel processing unit 1202 may be an integrated graphics processing unit (iGPU) or parallel processor included in the chipset of the motherboard.

### Exemplary Computing System

Systems with multiple GPUs and CPUs are used in a variety of industries as developers expose and leverage more parallelism in applications such as artificial intelligence computing. High-performance GPU-accelerated systems with tens to many thousands of compute nodes are deployed in data centers, research facilities, and supercomputers to solve ever larger problems. As the number of processing devices within the high-performance systems increases, the communication and data transfer mechanisms need to scale to support the increased bandwidth.

FIG. 16 is a conceptual diagram of a processing system 1600 implemented using the parallel processing unit 1202 of FIG. 12, in accordance with an embodiment. The processing system 1600 includes a central processing unit 1602, switch 1604, and multiple parallel processing unit 1202 modules each and respective memory 1220 modules. The NVLink 1216 provides high-speed communication links between each of the parallel processing unit 1202 modules. Although a particular number of NVLink 1216 and interconnect 1218 connections are illustrated in FIG. 16, the number of connections to each parallel processing unit 1202 and the central processing unit 1602 may vary. The switch 1604 interfaces between the interconnect 1218 and the central processing unit 1602. The parallel processing unit 1202 modules, memory 1220 modules, and NVLink 1216 connections may be situated on a single semiconductor platform to form a parallel processing module 1606. In an embodiment, the switch 1604 supports two or more protocols to interface between various different connections and/or links.

In another embodiment (not shown), the NVLink 1216 provides one or more high-speed communication links between each of the parallel processing unit modules (parallel processing unit 1202, parallel processing unit 1202, parallel processing unit 1202, and parallel processing unit 1202) and the central processing unit 1602 and the switch 1604 interfaces between the interconnect 1218 and each of the parallel processing unit modules. The parallel processing unit modules, memory 1220 modules, and interconnect 1218 may be situated on a single semiconductor platform to form a parallel processing module 1606. In yet another embodiment (not shown), the interconnect 1218 provides one or more communication links between each of the parallel processing unit modules and the central processing unit 1602 and the switch 1604 interfaces between each of the parallel processing unit modules using the NVLink 1216 to provide one or more high-speed communication links between the parallel processing unit modules. In another embodiment (not shown), the NVLink 1216 provides one or more high-speed communication links between the parallel processing unit modules and the central processing unit 1602 through the switch 1604. In yet another embodiment (not shown), the interconnect 1218 provides one or more communication links between each of the parallel processing unit modules directly. One or more of the NVLink 1216 high-speed communication links may be implemented as a physical NVLink interconnect or either an on-chip or on-die interconnect using the same protocol as the NVLink 1216.

In the context of the present description, a single semiconductor platform may refer to a sole unitary semiconductor-based integrated circuit fabricated on a die or chip. It should be noted that the term single semiconductor platform may also refer to multi-chip modules with increased connectivity which simulate on-chip operation and make substantial improvements over utilizing a conventional bus implementation. Of course, the various circuits or devices may also be situated separately or in various combinations of semiconductor platforms per the desires of the user. Alternately, the parallel processing module 1606 may be implemented as a circuit board substrate and each of the parallel processing unit modules and/or memory 1220 modules may be packaged devices. In an embodiment, the central processing unit 1602, switch 1604, and the parallel processing module 1606 are situated on a single semiconductor platform.

In an embodiment, the signaling rate of each NVLink 1216 is 20 to 25 Gigabits/second and each parallel processing unit module includes six NVLink 1216 interfaces (as shown in FIG. 16, five NVLink 1216 interfaces are included for each parallel processing unit module). Each NVLink 1216 provides a data transfer rate of 25 Gigabytes/second in each direction, with six links providing 300 Gigabytes/second. The NVLink 1216 can be used exclusively for PPU-to-PPU communication as shown in FIG. 16, or some combination of PPU-to-PPU and PPU-to-CPU, when the central processing unit 1602 also includes one or more NVLink 1216 interfaces.

In an embodiment, the NVLink 1216 allows direct load/store/atomic access from the central processing unit 1602 to each parallel processing unit module's memory 1220. In an embodiment, the NVLink 1216 supports coherency operations, allowing data read from the memory 1220 modules to be stored in the cache hierarchy of the central processing unit 1602, reducing cache access latency for the central processing unit 1602. In an embodiment, the NVLink 1216 includes support for Address Translation Services (ATS), enabling the parallel processing unit module to directly access page tables within the central processing unit 1602. One or more of the NVLink 1216 may also be configured to operate in a low-power mode.

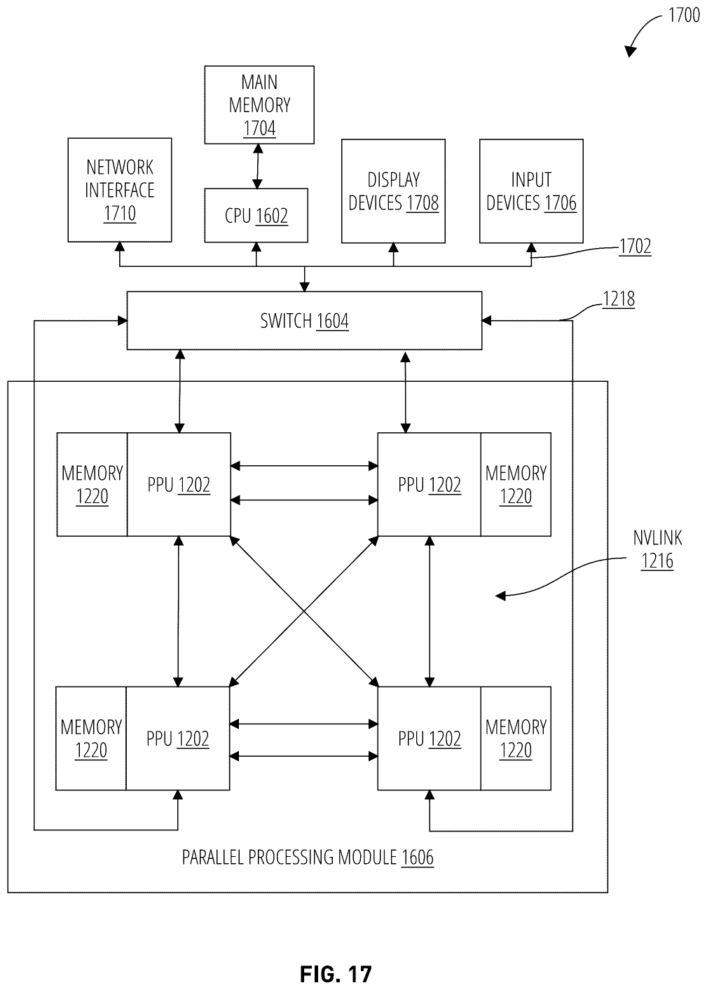

FIG. 17 depicts an exemplary processing system 1700 in which the various architecture and/or functionality of the various previous embodiments may be implemented. As shown, an exemplary processing system 1700 is provided including at least one central processing unit 1602 that is connected to a communications bus 1702. The communication communications bus 1702 may be implemented using any suitable protocol, such as PCI (Peripheral Component Interconnect), PCI-Express, AGP (Accelerated Graphics Port), HyperTransport, or any other bus or point-to-point communication protocol(s). The exemplary processing system 1700 also includes a main memory 1704. Control logic (software) and data are stored in the main memory 1704 which may take the form of random access memory (RAM).

The exemplary processing system 1700 also includes input devices 1706, the parallel processing module 1606, and display devices 1708, e.g. a conventional CRT (cathode ray tube), LCD (liquid crystal display), LED (light emitting diode), plasma display or the like. User input may be received from the input devices 1706, e.g., keyboard, mouse, touchpad, microphone, and the like. Each of the foregoing modules and/or devices may even be situated on a single semiconductor platform to form the exemplary processing system 1700. Alternately, the various modules may also be situated separately or in various combinations of semiconductor platforms per the desires of the user.

Further, the exemplary processing system 1700 may be coupled to a network (e.g., a telecommunications network, local area network (LAN), wireless network, wide area network (WAN) such as the Internet, peer-to-peer network, cable network, or the like) through a network interface 1710 for communication purposes.

The exemplary processing system 1700 may also include a secondary storage (not shown). The secondary storage includes, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive reads from and/or writes to a removable storage unit in a well-known manner.

Computer programs, or computer control logic algorithms, may be stored in the main memory 1704 and/or the secondary storage. Such computer programs, when executed, enable the exemplary processing system 1700 to perform various functions. The main memory 1704, the storage, and/or any other storage are possible examples of computer-readable media.

The architecture and/or functionality of the various previous figures may be implemented in the context of a general computer system, a circuit board system, a game console system dedicated for entertainment purposes, an application-specific system, and/or any other desired system. For example, the exemplary processing system 1700 may take the form of a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, a mobile phone device, a television, workstation, game consoles, embedded system, and/or any other type of logic.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

### Graphics Processing Pipeline

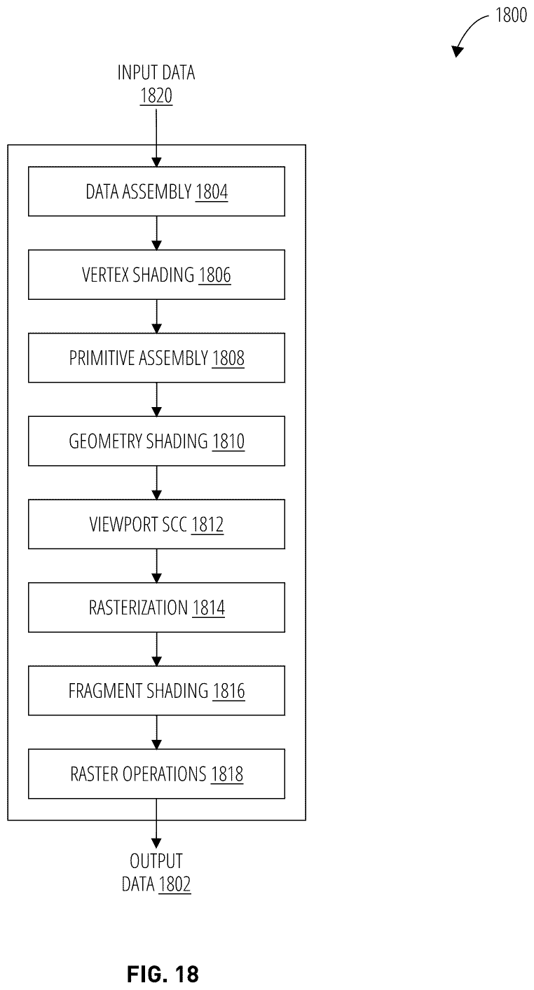

FIG. 18 is a conceptual diagram of a graphics processing pipeline 1800 implemented by the parallel processing unit 1202 of FIG. 12, in accordance with an embodiment. In an embodiment, the parallel processing unit 1202 comprises a graphics processing unit (GPU). The parallel processing unit 1202 is configured to receive commands that specify shader programs for processing graphics data. Graphics data may be defined as a set of primitives such as points, lines, triangles, quads, triangle strips, and the like. Typically, a primitive includes data that specifies a number of vertices for the primitive (e.g., in a model-space coordinate system) as well as attributes associated with each vertex of the primitive. The parallel processing unit 1202 can be configured to process the graphics primitives to generate a frame buffer (e.g., pixel data for each of the pixels of the display).

An application writes model data for a scene (e.g., a collection of vertices and attributes) to a memory such as a system memory or memory 1220. The model data defines each of the objects that may be visible on a display. The application then makes an API call to the driver kernel that requests the model data to be rendered and displayed. The driver kernel reads the model data and writes commands to the one or more streams to perform operations to process the model data. The commands may reference different shader programs to be implemented on the streaming multiprocessor 1500 modules of the parallel processing unit 1202 including one or more of a vertex shader, hull shader, domain shader, geometry shader, and a pixel shader. For example, one or more of the streaming multiprocessor 1500 modules may be configured to execute a vertex shader program that processes a number of vertices defined by the model data. In an embodiment, the different streaming multiprocessor 1500 modules may be configured to execute different shader programs concurrently. For example, a first subset of streaming multiprocessor 1500 modules may be configured to execute a vertex shader program while a second subset of streaming multiprocessor 1500 modules may be configured to execute a pixel shader program. The first subset of streaming multiprocessor 1500 modules processes vertex data to produce processed vertex data and writes the processed vertex data to the level two cache 1404 and/or the memory 1220. After the processed vertex data is rasterized (e.g., transformed from three-dimensional data into two-dimensional data in screen space) to produce fragment data, the second subset of streaming multiprocessor 1500 modules executes a pixel shader to produce processed fragment data, which is then blended with other processed fragment data and written to the frame buffer in memory 1220. The vertex shader program and pixel shader program may execute concurrently, processing different data from the same scene in a pipelined fashion until all of the model data for the scene has been rendered to the frame buffer. Then, the contents of the frame buffer are transmitted to a display controller for display on a display device.

The graphics processing pipeline 1800 is an abstract flow diagram of the processing steps implemented to generate 2D computer-generated images from 3D geometry data. As is well-known, pipeline architectures may perform long latency operations more efficiently by splitting up the operation into a plurality of stages, where the output of each stage is coupled to the input of the next successive stage. Thus, the graphics processing pipeline 1800 receives input data 601 that is transmitted from one stage to the next stage of the graphics processing pipeline 1800 to generate output data 1802. In an embodiment, the graphics processing pipeline 1800 may represent a graphics processing pipeline defined by the OpenGL R API. As an option, the graphics processing pipeline 1800 may be implemented in the context of the functionality and architecture of the previous Figures and/or any subsequent Figure(s).

As shown in FIG. 18, the graphics processing pipeline 1800 comprises a pipeline architecture that includes a number of stages. The stages include, but are not limited to, a data assembly 1804 stage, a vertex shading 1806 stage, a primitive assembly 1808 stage, a geometry shading 1810 stage, a viewport SCC 1812 stage, a rasterization 1814 stage, a fragment shading 1816 stage, and a raster operations 1818 stage. In an embodiment, the input data 1820 comprises commands that configure the processing units to implement the stages of the graphics processing pipeline 1800 and geometric primitives (e.g., points, lines, triangles, quads, triangle strips or fans, etc.) to be processed by the stages. The output data 1802 may comprise pixel data (e.g., color data) that is copied into a frame buffer or other type of surface data structure in a memory.

The data assembly 1804 stage receives the input data 1820 that specifies vertex data for high-order surfaces, primitives, or the like. The data assembly 1804 stage collects the vertex data in a temporary storage or queue, such as by receiving a command from the host processor that includes a pointer to a buffer in memory and reading the vertex data from the buffer. The vertex data is then transmitted to the vertex shading 1806 stage for processing.

The vertex shading 1806 stage processes vertex data by performing a set of operations (e.g., a vertex shader or a program) once for each of the vertices. Vertices may be, e.g., specified as a 4-coordinate vector (e.g., <x, y, z, w>) associated with one or more vertex attributes (e.g., color, texture coordinates, surface normal, etc.). The vertex shading 1806 stage may manipulate individual vertex attributes such as position, color, texture coordinates, and the like. In other words, the vertex shading 1806 stage performs operations on the vertex coordinates or other vertex attributes associated with a vertex. Such operations commonly including lighting operations (e.g., modifying color attributes for a vertex) and transformation operations (e.g., modifying the coordinate space for a vertex). For example, vertices may be specified using coordinates in an object-coordinate space, which are transformed by multiplying the coordinates by a matrix that translates the coordinates from the object-coordinate space into a world space or a normalized-device-coordinate (NCD) space. The vertex shading 1806 stage generates transformed vertex data that is transmitted to the primitive assembly 1808 stage.

The primitive assembly 1808 stage collects vertices output by the vertex shading 1806 stage and groups the vertices into geometric primitives for processing by the geometry shading 1810 stage. For example, the primitive assembly 1808 stage may be configured to group every three consecutive vertices as a geometric primitive (e.g., a triangle) for transmission to the geometry shading 1810 stage. In some embodiments, specific vertices may be reused for consecutive geometric primitives (e.g., two consecutive triangles in a triangle strip may share two vertices). The primitive assembly 1808 stage transmits geometric primitives (e.g., a collection of associated vertices) to the geometry shading 1810 stage.

The geometry shading 1810 stage processes geometric primitives by performing a set of operations (e.g., a geometry shader or program) on the geometric primitives. Tessellation operations may generate one or more geometric primitives from each geometric primitive. In other words, the geometry shading 1810 stage may subdivide each geometric primitive into a finer mesh of two or more geometric primitives for processing by the rest of the graphics processing pipeline 1800. The geometry shading 1810 stage transmits geometric primitives to the viewport SCC 1812 stage.

In an embodiment, the graphics processing pipeline 1800 may operate within a streaming multiprocessor and the vertex shading 1806 stage, the primitive assembly 1808 stage, the geometry shading 1810 stage, the fragment shading 1816 stage, and/or hardware/software associated therewith, may sequentially perform processing operations. Once the sequential processing operations are complete, in an embodiment, the viewport SCC 1812 stage may utilize the data. In an embodiment, primitive data processed by one or more of the stages in the graphics processing pipeline 1800 may be written to a cache (e.g. L1 cache, a vertex cache, etc.). In this case, in an embodiment, the viewport SCC 1812 stage may access the data in the cache. In an embodiment, the viewport SCC 1812 stage and the rasterization 1814 stage are implemented as fixed function circuitry.

The viewport SCC 1812 stage performs viewport scaling, culling, and clipping of the geometric primitives. Each surface being rendered to is associated with an abstract camera position. The camera position represents a location of a viewer looking at the scene and defines a viewing frustum that encloses the objects of the scene. The viewing frustum may include a viewing plane, a rear plane, and four clipping planes. Any geometric primitive entirely outside of the viewing frustum may be culled (e.g., discarded) because the geometric primitive will not contribute to the final rendered scene. Any geometric primitive that is partially inside the viewing frustum and partially outside the viewing frustum may be clipped (e.g., transformed into a new geometric primitive that is enclosed within the viewing frustum. Furthermore, geometric primitives may each be scaled based on a depth of the viewing frustum. All potentially visible geometric primitives are then transmitted to the rasterization 1814 stage.

The rasterization 1814 stage converts the 3D geometric primitives into 2D fragments (e.g. capable of being utilized for display, etc.). The rasterization 1814 stage may be configured to utilize the vertices of the geometric primitives to setup a set of plane equations from which various attributes can be interpolated. The rasterization 1814 stage may also compute a coverage mask for a plurality of pixels that indicates whether one or more sample locations for the pixel intercept the geometric primitive. In an embodiment, z-testing may also be performed to determine if the geometric primitive is occluded by other geometric primitives that have already been rasterized. The rasterization 1814 stage generates fragment data (e.g., interpolated vertex attributes associated with a particular sample location for each covered pixel) that are transmitted to the fragment shading 1816 stage.

The fragment shading 1816 stage processes fragment data by performing a set of operations (e.g., a fragment shader or a program) on each of the fragments. The fragment shading 1816 stage may generate pixel data (e.g., color values) for the fragment such as by performing lighting operations or sampling texture maps using interpolated texture coordinates for the fragment. The fragment shading 1816 stage generates pixel data that is transmitted to the raster operations 1818 stage.

The raster operations 1818 stage may perform various operations on the pixel data such as performing alpha tests, stencil tests, and blending the pixel data with other pixel data corresponding to other fragments associated with the pixel. When the raster operations 1818 stage has finished processing the pixel data (e.g., the output data 1802), the pixel data may be written to a render target such as a frame buffer, a color buffer, or the like.

It will be appreciated that one or more additional stages may be included in the graphics processing pipeline 1800 in addition to or in lieu of one or more of the stages described above. Various implementations of the abstract graphics processing pipeline may implement different stages. Furthermore, one or more of the stages described above may be excluded from the graphics processing pipeline in some embodiments (such as the geometry shading 1810 stage). Other types of graphics processing pipelines are contemplated as being within the scope of the present disclosure. Furthermore, any of the stages of the graphics processing pipeline 1800 may be implemented by one or more dedicated hardware units within a graphics processor such as parallel processing unit 1202. Other stages of the graphics processing pipeline 1800 may be implemented by programmable hardware units such as the streaming multiprocessor 1500 of the parallel processing unit 1202.

The graphics processing pipeline 1800 may be implemented via an application executed by a host processor, such as a CPU. In an embodiment, a device driver may implement an application programming interface (API) that defines various functions that can be utilized by an application in order to generate graphical data for display. The device driver is a software program that includes a plurality of instructions that control the operation of the parallel processing unit 1202. The API provides an abstraction for a programmer that lets a programmer utilize specialized graphics hardware, such as the parallel processing unit 1202, to generate the graphical data without requiring the programmer to utilize the specific instruction set for the parallel processing unit 1202. The application may include an API call that is routed to the device driver for the parallel processing unit 1202. The device driver interprets the API call and performs various operations to respond to the API call. In some instances, the device driver may perform operations by executing instructions on the CPU. In other instances, the device driver may perform operations, at least in part, by launching operations on the parallel processing unit 1202 utilizing an input/output interface between the CPU and the parallel processing unit 1202. In an embodiment, the device driver is configured to implement the graphics processing pipeline 1800 utilizing the hardware of the parallel processing unit 1202.

Various programs may be executed within the parallel processing unit 1202 in order to implement the various stages of the graphics processing pipeline 1800. For example, the device driver may launch a kernel on the parallel processing unit 1202 to perform the vertex shading 1806 stage on one streaming multiprocessor 1500 (or multiple streaming multiprocessor 1500 modules). The device driver (or the initial kernel executed by the parallel processing unit 1202) may also launch other kernels on the parallel processing unit 1202 to perform other stages of the graphics processing pipeline 1800, such as the geometry shading 1810 stage and the fragment shading 1816 stage. In addition, some of the stages of the graphics processing pipeline 1800 may be implemented on fixed unit hardware such as a rasterizer or a data assembler implemented within the parallel processing unit 1202. It will be appreciated that results from one kernel may be processed by one or more intervening fixed function hardware units before being processed by a subsequent kernel on a streaming multiprocessor 1500.

### LISTING OF DRAWING ELEMENTS

102 cell layout
104 netlist
106 layout template
108 placer
110 lattice graph generator
112 routability model
114 metric control generator
116 multi-objective optimizer
118 router
120 dynamic pin allocation
202 lattice graph
302 power net
304 ground net
306 device gate
308 device active region
402 graph neural network
404 multi-layer perceptron
406 multi-layer perceptron
408 multi-layer perceptron
602 virtual node
604 virtual node
606 unidirectional edge
608 external pin layer grid node
802 LISD layer routing
804 M2 layer routing
806 M1 layer routing
900 circuit layout router
902 layout with device placement
904 genetic router
906 candidate routed layouts
908 reinforced learning model
910 DRC corrected routed layouts
912 final routed layout
1000 incremental routing process
1002 block
1004 block
1006 block
1100 genetic routing algorithm
1202 parallel processing unit
1204 I/O unit
1206 front-end unit
1208 scheduler unit
1210 work distribution unit
1212 hub
1214 crossbar
1216 NVLink
1218 interconnect
1220 memory
1300 general processing cluster
1302 pipeline manager
1304 pre-raster operations unit
1306 raster engine
1308 work distribution crossbar
1310 memory management unit
1312 data processing cluster
1314 primitive engine
1316 M-pipe controller
1400 memory partition unit
1402 raster operations unit
1404 level two cache
1406 memory interface
1500 streaming multiprocessor
1502 instruction cache
1504 scheduler unit
1506 register file
1508 core
1510 special function unit
1512 load/store unit
1514 interconnect network
1516 shared memory/L1 cache
1518 dispatch
1600 processing system
1602 central processing unit
1604 switch
1606 parallel processing module
1700 exemplary processing system
1702 communications bus
1704 main memory
1706 input devices
1708 display devices
1710 network interface
1800 graphics processing pipeline
1802 output data
1804 data assembly
1806 vertex shading
1808 primitive assembly
1810 geometry shading
1812 viewport SCC
1814 rasterization
1816 fragment shading
1818 raster operations
1820 input data

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter).

Within this disclosure, different entities (which may variously be referred to as “units,” “circuits,” other components, etc.) may be described or claimed as “configured” to perform one or more tasks or operations. This formulation-[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112 (f) for that claim element. Accordingly, claims in this application that do not otherwise include the “means for” [performing a function] construct should not be interpreted under 35 U.S.C § 112 (f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the invention as claimed. The scope of inventive subject matter is not limited to the depicted embodiments but is rather set forth in the following Claims.

What is claimed is:

1. A logic cell layout process comprising:
transforming a circuit netlist for the logic cell into a plurality of lattice graphs;
operating a routability model to transform the lattice graphs into congestion probabilities and routability probabilities for the logic cell layout; and
applying the congestion probabilities and routability probabilities to influence transistor device placement in the logic cell layout.

2. The logic cell layout process of claim 1, wherein the lattice graphs comprise front-end-of-line (FEOL) grids, external pin grids, and circuit nets for the transistor device placements.

3. The logic cell layout process of claim 1, wherein the transistor device placement in the logic cell layout is carried out by a simulated annealing-based placer.

4. The logic cell layout process of claim 1, wherein the congestion probabilities and routability probabilities are applied as a weighted combination to influence the transistor device placement.

5. The logic cell layout process of claim 4, wherein weights of the weighted combination are determined via a multi-objective optimization.

6. The logic cell layout process of claim 1, further comprising:
combining the routability probabilities with pin density values to generate a pin access value for the logic cell layout overall; and
combining the routability probabilities with the congestion probabilities to generate a congestion value for the logic cell layout overall.

7. The logic cell layout process of claim 6, further comprising:
combining the pin access value and the congestion value to generate a routability value for the logic cell layout overall.

8. A device comprising:
at least one computer processor;
a non-volatile computer-readable medium comprising instructions that, when executed by the at least one computer processor, configure the device to:
generate a moving window across a circuit layout;
at each of a plurality of locations of the moving window, determine a pin density;
combine the pin densities from the moving window locations into a routing congestion metric for the circuit layout; and
control a device placer with the congestion metric on the circuit layout.

9. The device of claim 8, wherein determining the pin density at a location of the moving window comprises:
determining a number of required contacts to a metal layer in the location of the moving window; and
adding a number of crossing nets of the window to the number of required contacts.

10. The device of claim 8, wherein the metal layer is a lowest metal layer.

11. The device of claim 8, wherein the number of crossing nets excludes nets that connect within the window.

12. The device of claim 8, wherein the number of crossing nets excludes power and ground nets.

13. The device of claim 8, wherein the instructions, when executed by the at least one computer processor, further configure the device to:
set a size of the window according to contact rules and end-of-line spacing rules for a technology node of the circuit layout.

14. The device of claim 8, wherein the instructions, when executed by the at least one computer processor, further configure the device to:
apply the routing congestion metric for the circuit layout to influence transistor device placement in the circuit layout.

15. The device of claim 14, wherein the transistor device placement in the circuit layout is carried out by a simulated annealing-based placer.

16. The device of claim 8, wherein the instructions, when executed by the at least one computer processor, further configure the device to:
utilize the routing congestion metric for the circuit layout in a multi-objective optimization by the device placer.

17. The device of claim 8, wherein the instructions, when executed by the at least one computer processor, further configure the device to:
apply weights to one or both of a number of required contacts to a metal layer in the location of the moving window and a number of crossing nets of the window, based on a transistor pin structure constraint for the window.

18. The device of claim 8, wherein the instructions, when executed by the at least one computer processor, further configure the device to:
adjust the circuit layout to smooth a routing congestion metric across the circuit layout.

19. A system comprising:
a logic cell device placer;
a controller for the device placer, the controller comprising:
a routability model to transform a plurality of lattice graphs for a circuit into routability probabilities for a layout of the circuit;
logic to:
determine pin density at a plurality of locations of the layout; and
form a control signal to the device placer, the control signal formed by combining the pin densities and routing probabilities into a routing difficulty metric for the layout.

20. The system of claim 19, wherein the device placer comprises a simulated annealing algorithm.

21. The system of claim 19, further comprising a genetic algorithm router.
